(19) United States
(12) Patent Application Publication
(10) Pub. No.: US 2019/0273494 A1
(43) Pub. Date: Sep. 5, 2019

(54) GATE DRIVING DEVICE

(71) Applicant: DENSO CORPORATION, Kariya-city (JP)

(72) Inventors: Daisuke MATSUMOTO, Kariya-city (JP); Yasutaka SENDA, Kariya-city (JP); Yusuke MICHISHITA, Kariya-city (JP)

(21) Appl. No.: 16/414,808

(22) Filed: May 17, 2019

Related U.S. Application Data
(63) Continuation of application No. PCT/JP2017/039556, filed on Nov. 1, 2017.

(30) Foreign Application Priority Data
Nov. 25, 2016 (JP) 2016-228956
May 24, 2017 (JP) 2017-102621

(51) Int. Cl. H03K 17/567; H03K 17/687; H03K 17/60

(52) U.S. Cl. CPC H03K 17/567; H03K 17/60; H03K 17/687

(57) ABSTRACT

A gate driving device drives a plurality of semiconductor elements connected in parallel. The plurality of semiconductor elements includes a start-up semiconductor element and a next-stage driving semiconductor element. The gate driving device includes a current detection circuit, a constant current circuit, a selector switch, and a control circuit. In start-up control performed by the control circuit, the control circuit applies a gate signal to the start-up semiconductor element at a constant current to turn on the start-up semiconductor element. In next-stage drive control performed by the control circuit, in response to the current of the semiconductor element reaches a threshold current, the control circuit sets the selector switch to an operating state and applies a gate signal to the next-stage driving semiconductor element at a constant voltage to turn on the next-stage driving semiconductor element.

### CROSS REFERENCE TO RELATED APPLICATIONS

The present application is a continuation application of International Patent Application No. PCT/JP2017/039556 filed on Nov. 1, 2017, which designated the U.S. and claims the benefit of priority from Japanese Patent Application No. 2016-228956 filed on Nov. 25, 2016 and Japanese Patent Application No. 2017-102621 filed on May 24, 2017. The entire disclosures of all of the above applications are incorporated herein by reference.

### TECHNICAL FIELD

The present disclosure relates to a gate driving device.

### BACKGROUND

In a gate driving device for driving a gate of, for example, an insulated gate bipolar transistor (IGBT) as a gate-driven semiconductor element, a configuration may be adopted where a plurality of semiconductor power elements are connected in parallel to feed power to a load. This is because, when a large current is allowed to flow, the parallel connection can lower the on-resistance of the semiconductor power element to reduce an on-resistance loss.

### SUMMARY

The present disclosure describes a gate driving device for driving a plurality of gate-driven semiconductor elements connected in parallel.

### BRIEF DESCRIPTION OF DRAWINGS

The above and other objects, features and advantages of the present disclosure will become more apparent from the following detailed description made with reference to the accompanying drawings. In the drawings:

FIG. 1 is a schematic electrical configuration diagram showing a first embodiment;

FIG. 2 is a specific electrical configuration diagram;

FIG. 3 is a flowchart of a drive control operation;

FIGS. 4A to 4F are a time chart (part 1);

FIGS. 5A to 5F are a time chart (part 2);

FIG. 6 is a schematic electrical configuration diagram showing a second embodiment;

FIG. 7 is a flowchart of drive control operation;

FIGS. 8A to 8H are a time chart (part 1);

FIGS. 9A to 9H are a time chart (part 2);

FIGS. 10A to 10H are a time chart (part 3);

FIG. 11 is a diagram showing a relationship between the number of IGBTs driven and the loss;

FIG. 12 is a flowchart of drive control operation showing a third embodiment;

FIGS. 13A to 13F are a time chart (part 1);

FIGS. 14A to 14F are a time chart (part 2);

FIGS. 15A to 15G are a time chart showing a fourth embodiment;

FIG. 16 is a flowchart of a drive control operation showing a fifth embodiment;

FIGS. 17A to 17F are a time chart;

FIG. 18 is an electrical configuration diagram showing a sixth embodiment;

FIG. 19 is a diagram showing a flow of on-time processing;

FIG. 20 is a diagram showing a flow of off-time processing;

FIGS. 21A to 21I are a time chart (part 1) showing changes in signals, currents, and voltages of respective parts; and

FIGS. 22A to 221 are a time chart (part 2) showing changes in signals, currents, and voltages of respective parts.

### DETAILED DESCRIPTION

With the parallel connection and driving of the plurality of semiconductor power elements, the switching loss increases in proportion to the number of semiconductor power elements, and the loss is particularly large when switching is performed with a high collector voltage. Therefore, an increase in the semiconductor power elements to be connected in parallel to allow a large current to flow may lead to an increase in the switching loss.

In one or more embodiments described in the present disclosure, a gate driving device controls drive while reducing the switching loss as much as possible in a configuration where a plurality of semiconductor elements are connected in parallel to allow a large current to flow in a state where a high voltage is applied.

In one or more embodiments described in the present disclosure, a gate driving device turns off a gate-driven semiconductor device without damaging the semiconductor device while reducing the switching loss in control of a configuration in which a plurality of the gate-driven semiconductor devices are connected in parallel. According to a first aspect of the present disclosure, a gate driving device for driving a plurality of gate-driven semiconductor elements connected in parallel. The semiconductor elements include a start-up semiconductor element and at least one next-stage driving semiconductor element having a final-stage driving semiconductor element. The gate driving device includes: a current detection circuit that detects a current of each of remaining semiconductor elements other than the final-stage driving semiconductor element among the plurality of semiconductor elements; a constant current circuit that performs gate drive on the start-up semiconductor element at a constant voltage; a selector switch that disables the constant current circuit and performs gate drive on the next-stage driving semiconductor element and the final-stage driving semiconductor element at a constant voltage; and a control circuit that drives and controls the plurality of semiconductor elements. The control circuit receives a driving signal for a turn-on operation from outside to execute a start-up control and a next-stage drive control, and to repetitively execute the next-stage drive control in response to the next-stage driving semiconductor element in an off-state being subsequently present. In the start-up control, the control circuit applies a gate signal to the start-up semiconductor element at a constant current by the constant current circuit to turn on the start-up semiconductor element. In the next-stage drive control, the control circuit sets the selector switch into an operating state and applies the gate signal to the next-stage driving semiconductor element in an off-state at a constant voltage to turn on the next-stage driving semiconductor element, in response to a current detected by the current detection circuit provided in the semiconductor element being turned on reaching a threshold current. The threshold current is set such that a sum of an on-resistance loss and a switching loss caused by all the semiconductor elements in an on-state is smaller than the sum of the on-resistance loss and the switching loss before execution of the next-stage drive control, in response to the next-stage driving semiconductor element among the plurality of semiconductor elements being turned on to allow a current to flow.

By adopting the above configuration, when a drive signal for turn-on operation is applied from the outside, in the start-up control, the control circuit applies a gate signal to the start-up semiconductor element at a constant current by the constant current circuit to turn on the start-up semiconductor element, and in the next-stage drive control, when the current detected by the current detection circuit provided in the semiconductor element turned on reaches a threshold current, the control circuit sets the selector switch into an operating state and applies a gate signal to the next-stage driving semiconductor element in an off-state at a constant voltage to turn on the next-stage driving semiconductor element in the off-state. Thereafter, when the next-stage driving semiconductor element in the off-state is present, the control circuit repeatedly performs the next-stage drive control.

In this case, the threshold current is set such that the sum of an on-resistance loss and a switching loss caused by all semiconductor elements in the on-state is the smallest when the next-stage driving semiconductor element among the plurality of semiconductor elements is turned on to allow current to flow. Generally, in the gate-driven semiconductor device, the on-resistance loss and the switching loss have the trade-off relationship, so that the total loss can be minimized by setting the threshold current as described above, to optimize the number of semiconductor elements to be driven.

According to a second aspect of the present disclosure, a gate driving device turns on and off a plurality of gate-driven semiconductor elements connected in parallel, and the gate driving device sets a semiconductor element to be held in an on-state among the plurality of semiconductor elements based on a current flowing in the plurality of semiconductor elements under a condition with a switching loss and an on-resistance loss associated with a turn-on operation resulting in decrease. The gate driving device includes: a normal gate-off circuit that turns off all the plurality of semiconductor elements; and a high-speed gate-off circuit that turns off a part of the plurality of semiconductor elements in response to the part of the semiconductor elements in the on-state. The normal gate-off circuit changes a gate voltage at a slower speed to turn off the plurality of semiconductor elements so that a surge current generated in turning off the plurality of semiconductor elements is equal to or smaller than a breakdown tolerance. The high-speed gate-off circuit changes the gate voltage at a faster speed than the normal gate-off circuit to turn off the part of the plurality of semiconductor elements.

By adopting the above configuration, in the turn-on operation, based on the current flowing through the plurality of semiconductor elements, one to be held in the on-state among the plurality of semiconductor elements is set under a condition such that the switching loss and the on-loss associated with the turn-on operation are reduced, and the other ones are turned off. In the turn-off operation, in a case where a plurality of semiconductor elements are to be turned off simultaneously, a normal gate-off path is formed by a normal gate-off circuit to turn off the plurality of semiconductor elements. When some of the plurality of semiconductor elements are turned off while one in the on-state is present, a high-speed gate-off path is formed by the high-speed gate-off circuit to turn off the ones to be turned off.

Thus, in a case where all of the plurality of semiconductor elements are to be turned off, when a normal gate-off circuit is used to perform the turn-off operation, the gate voltage changes at a low speed so that a surge current generated at the off-time can be made equal to or smaller than a breakdown tolerance. In addition, in a case where some of the plurality of semiconductor elements are turned off while one in the on-state is present, when the high-speed gate-off circuit is used to turn off some semiconductor elements, the surge current generated at the off-time is small due to the presence of the one in the on-state, and hence the turning-off can be performed at a high speed.

### First Embodiment

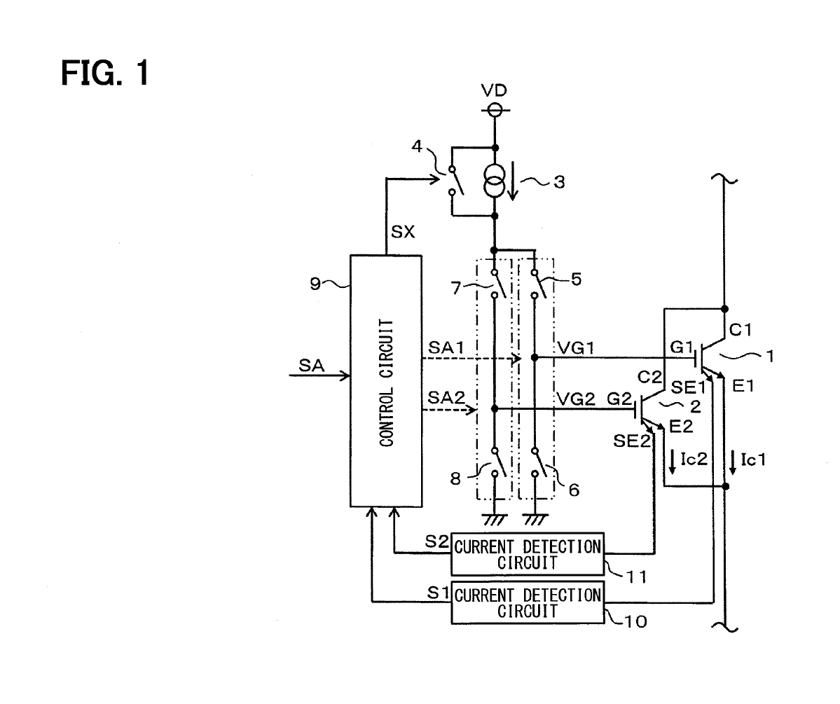

Hereinafter, a first embodiment will be described with reference to FIG. 1 to FIGS. 5A to 5F.

FIG. 1 shows a basic configuration of an electrical configuration. In this embodiment, two IGBTs 1, 2 are used as a plurality of gate-control semiconductor elements. The IGBT 1 has a sense emitter SE1 for monitoring a current in addition to a collector C1, an emitter E1, and a gate G1. Likewise, the IGBT 2 has a sense emitter SE2 for monitoring a current in addition to a collector C2, an emitter E2, and a gate G2.

The IGBTs 1, 2 are provided in a power supply path to a load (not shown), and have a configuration of a parallel drive system in which the collectors C1, C2 are connected in common and the emitters E1, E2 are connected in common. Gate drive voltages VG1, VG2 to the two IGBTs 1, 2 are configured to be supplied from a direct-current (DC) power source VD via a parallel circuit of a constant current circuit 3 and a selector switch 4.

The gate drive voltage VG1 is applied to the gate G1 of the IGBT 1 from the constant current circuit 3 via a gate current cutoff switch 5. Further, the gate G1 of the IGBT 1 is connected to a ground via a gate-off switch 6. The gate drive voltage VG2 is applied to the gate G2 of the IGBT 2 from the constant current circuit 3 via a gate current cutoff switch 7. Further, the gate G2 of the IGBT 2 is connected to a ground via a gate-off switch 8.

A control circuit 9 is constituted of a logic circuit including a gate drive circuit and the like and applies gate drive signals SA1, SA2 for the IGBTs 1, 2 according to a drive signal SA from the outside. Current detection circuits 10, 11 respectively receive inputs of signals corresponding to collector-emitter currents Ic1, Ic2 from the sense emitters SE1, SE2 of the IGBTs 1, 2, and output current detection signals S1, S2 to the control circuit 9. In accordance with the current detection signals S1, S2, the control circuit 9 performs on/off control of the selector switch 4, the current cutoff switches 5, 7, and the gate-off switches 6, 8 in a manner described later.

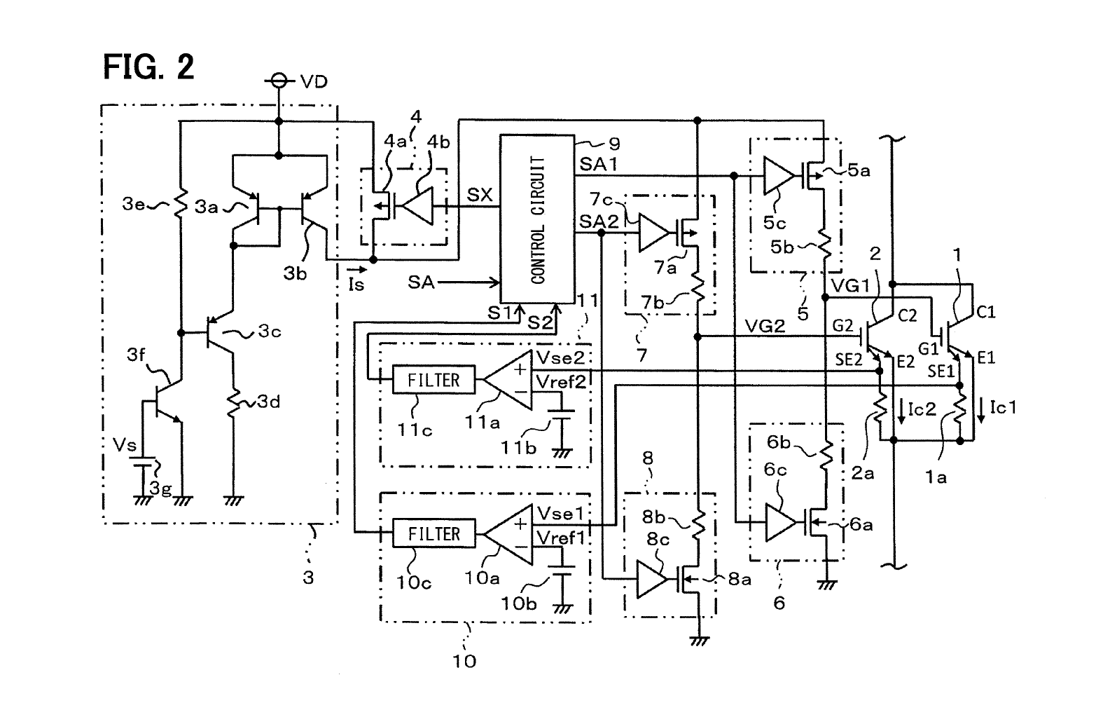

FIG. 2 shows a specific configuration of each part of the above configuration.

The sense emitter SE1 of the IGBT 1 is connected to the emitter E1 via the current detection resistor 1 a and is provided so as to output a terminal voltage Vse1 of the current detection resistor 1a as a detection signal of the current Ic1 of the IGBT 1.

The sense emitter SE2 of the IGBT 2 is connected to the emitter E2 via the current detection resistor 2a and is provided so as to output a terminal voltage Vse2 of a current detection resistor 2a as a detection signal of the current Ic2 of the IGBT 2.

The constant current circuit 3 is made up of pnp-type transistors 3a, 3b constituting a current mirror circuit, a transistor 3c for drawing a constant current, resistors 3d, 3e, a transistor 3f, and a reference power source 3g. The constant current circuit 3 allows a predetermined current to flow to the transistor 3a by a reference voltage Vrefc that is set by the reference power source 3g, and supplies a constant current Is from a power source VD to the gates of the IGBTs 1, 2 via a transistor 3b. The selector switch 4 connected in parallel to the transistor 3b of the constant current circuit 3 short-circuits the emitter and collector of the transistor 3b of the constant current circuit 3 and applies the power source VD directly to the gates of the IGBTs 1, 2. The selector switch 4 includes a p-channel metal-oxide-semiconductor field-effect transistor (MOSFET) 4a and a buffer circuit 4b connected to the gate. In the buffer circuit 4b, a switching signal SX is supplied from the control circuit 9.

The current cutoff switch 5 is formed by connecting a p-channel MOSFET 5a and an input resistor 5b in series, and to the gate of the MOSFET 5a, a buffer circuit 5c is connected and a gate drive signal SA1 is applied from the control circuit 9. Similarly, the power shutoff switch 7 is formed by connecting a p-channel MOSFET 7a and an input resistor 7b in series, and to the gate of the MOSFET 7a, a buffer circuit 7c is connected and a gate drive signal SA2 is applied from the control circuit 9.

The gate-off switch 6 is formed by connecting an n-channel MOSFET 6a and an input resistor 6b in series, and to the gate of the MOSFET 6a, a buffer circuit 6c is connected and the gate drive signal SA1 is applied from the control circuit 9. Similarly, the gate-off switch 8 is formed by connecting a n-channel MOSFET 8a and an input resistor 8b in series, and to the gate of the MOSFET 8a, a buffer circuit 8c is connected and the gate drive signal SA2 is applied from the control circuit 9.

The current detection circuit 10 includes a comparator 10a, a reference power source 10b, and a filter 10c. The current detection signal Vse1 appearing at the sense emitter SE1 of the IGBT 1 is input into the non-inverting input terminal of the comparator 10a, and the reference voltage Vref1 is input into the inverting input terminal of the comparator 10a by the reference power source 10b that sets a threshold current value Ith1. The comparator 10a compares the current detection signal Vse1 of the IGBT 1 with the reference voltage Vref1, outputs a high-level detection signal S1 when the current detection signal Vse1 is equal to or higher than the reference voltage Vref1, and inputs the detection signal S1 to the control circuit 9 via the filter 10c. When the high-level detection signal S1 continues for a certain time, the filter 10c outputs the detection signal S1 to the control circuit.

The current detection circuit 11 includes a comparator 11a, a reference power source 11b, and a filter 11c. The current detection signal Vse2 appearing at the sense emitter SE2 of the IGBT 2 is input into the non-inverting input terminal of the comparator 11a, and the reference voltage Vref2 is input into the inverting input terminal of the comparator 11a by the reference power source 11b that sets a threshold current value Ith1. The comparator 11a compares the current detection signal Vse2 of the IGBT 2 with the reference voltage Vref2, outputs a high-level detection signal S2 when the voltage is equal to or higher than the reference voltage Vref2, and inputs the detection signal S2 to the control circuit 9 via the filter 11c. When the high-level detection signal S2 continues for a certain time, the filter 11c outputs the detection signal S2 to the control circuit.

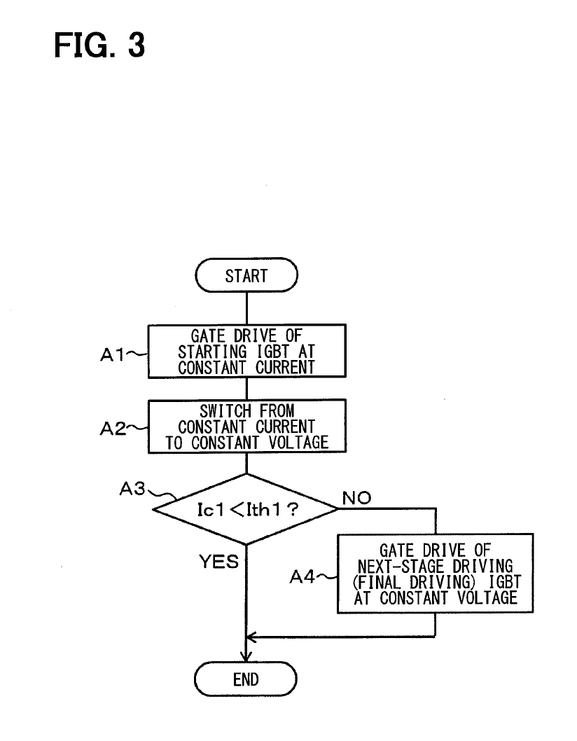

Next, the action of the above configuration will be described with reference also to FIG. 3 to FIGS. 5A to 5F.

FIG. 3 shows the flow of the gate drive control operation of the IGBTs 1, 2 by the logic function of the control circuit 9. In a standby state, the control circuit 9 outputs a high-level signal SX that holds the off-state to the selector switch 4, whereby the power source VD allows a flow of the constant current Is generated in the constant current circuit 3 to supply the gate drive voltage VG1 or VG2.

In a state where the IGBT 1, 2 are not driven, the control circuit 9 outputs high-level gate drive signals SA1, SA2 to the IGBTs 1, 2. Thereby, the respective MOSFETs 5a, 7a of the current cutoff switches 5, 7 are held in the off-state, and the MOSFETs 6a, 8a of the gate-off switches 6, 8 are held in the on-state. The gate G1 of the IGBT 1 is connected to the ground via the MOSFET 6a, while the gate G2 of the IGBT 2 is connected to the ground via the MOSFET 8a, and both the gates are held in the off-state.

When the drive signal SA is applied from the outside, the control circuit 9 outputs a low-level gate drive signal SA1 for driving the IGBT 1 which is a start-up semiconductor element with a constant current as a step A1. With the gate drive signal SA1, the MOSFET 6a of the gate-off switch 6 is turned off, and further, the MOSFET 5a of the current cutoff switch 5 is driven to be turned on. In the IGBT 1, the gate current Is flows from the power source VD via the constant current circuit 3 to the gate G1, and the gate drive voltage VG1 is supplied thereto. Hence, a gate voltage VG1 is applied to the IGBT 1 with dV/dt in a relatively gentle state, so that it is possible to drive the IGBT 1 in a state where variations in switching loss are reduced.

Thereafter, when the gate voltage of the IGBT 1 becomes stable, the control circuit 9 outputs a low-level switching signal SX to the buffer circuit 4b of the selector switch 4 in step A2. Thereby, the MOSFET 4a is turned on, so that the constant-current supply state by the constant current circuit 3 is stopped and the state is switched to the constant-voltage supply state in which the power source VD is supplied directly.

At this time, the current detection circuit 10 detects the current Ic1 of the IGBT 1. In the current detection circuit 10, the detection voltage Vse1 corresponding to the current value Ic1 of the IGBT 1 is input, and when the detection voltage Vse1 is equal to or higher than the reference voltage Vref1 for setting the threshold current Ith1, the current detection circuit 10 outputs the detection signal S1 to the control circuit 9. When the level of the detection voltage Vse1 rises and a high-level signal continues for a predetermined time or longer from the comparator 10a, the detection signal S1 is output from the filter 10c.

When the current value Ic1 of the IGBT 1 by the current detection circuit 10 is smaller than the threshold current Ith1, the control circuit 9 maintains the on-state of the IGBT 1 alone as YES in step A3. When the current value Ic1 becomes equal to or greater than the threshold current Ith1 and the detection signal S1 is output, the control circuit 9 proceeds to step A4 and drives the IGBT 2 at a constant voltage. The control circuit 9 outputs the gate drive signal SA2 to the IGBT 2 in addition to the IGBT 1. With the gate drive signal SA2, the MOSFET 8a of the gate-off switch 8 is turned off, and further, the MOSFET 7a of the current cutoff switch 7 is driven to be turned on. In the IGBT 2, the gate voltage is applied to the gate G2 from the power source VD via the MOSFET 4a of the selector switch 4. At this time, since the voltage applied across the drain and the source is low in the IGBT 2 because the IGBT 1 is already on, the loss can be reduced by performing the constant voltage drive.

In addition, by driving the two IGBTs 1, 2, it is possible to allow the entire current to flow in a state where the on-resistance is reduced as a whole, and reduce the on-resistance loss.

In the above operation, the value of the threshold current Ith1 of the current detection circuit 10 is set to such a level that, when a collector current Ic1 of the IGBT 1 further increases, the loss due to the on-resistance of the IGBT 1 increases, and even when the IGBT 2 is also driven to increase the switching loss, the loss due to the on-resistance is reduced, to enable reduction in loss as whole.

Thereby, in order to reduce variations in switching loss at the time of initial driving, it is possible to perform turn-on operation where the IGBT 1 is driven with the constant current Is, and when the current Ic1 of the IGBT 1 becomes equal to or greater than the threshold current Ith1, the IGBT 2 being the next-stage driving semiconductor element is driven with a constant voltage VD, so that the on operation where dV/dt is raised to reduce the loss can be performed.

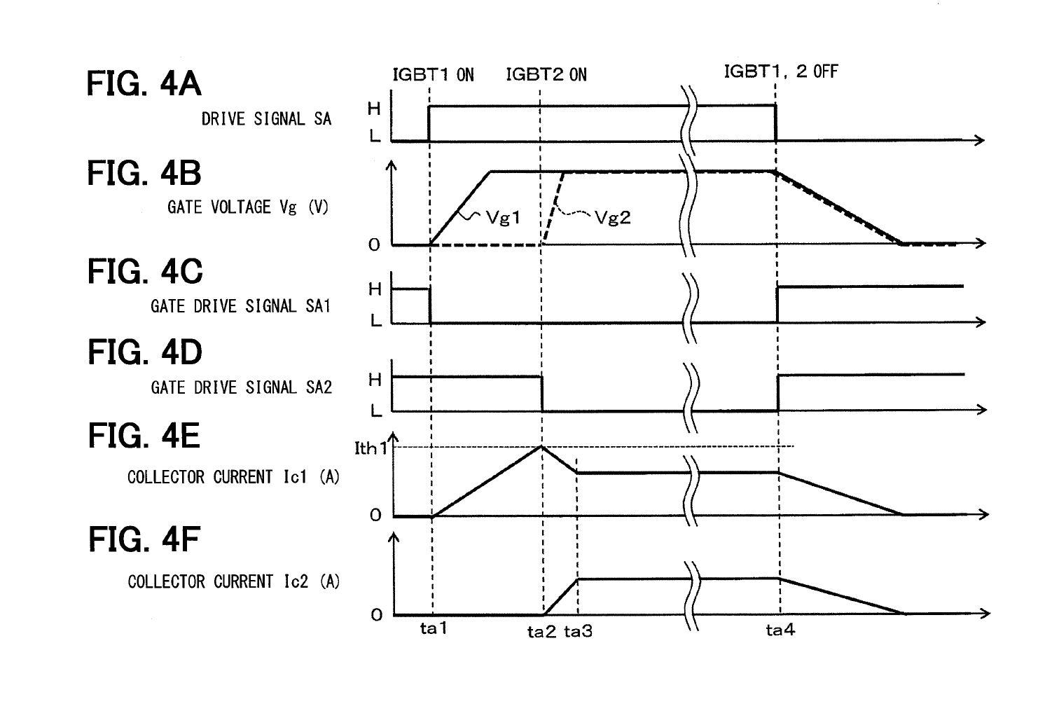

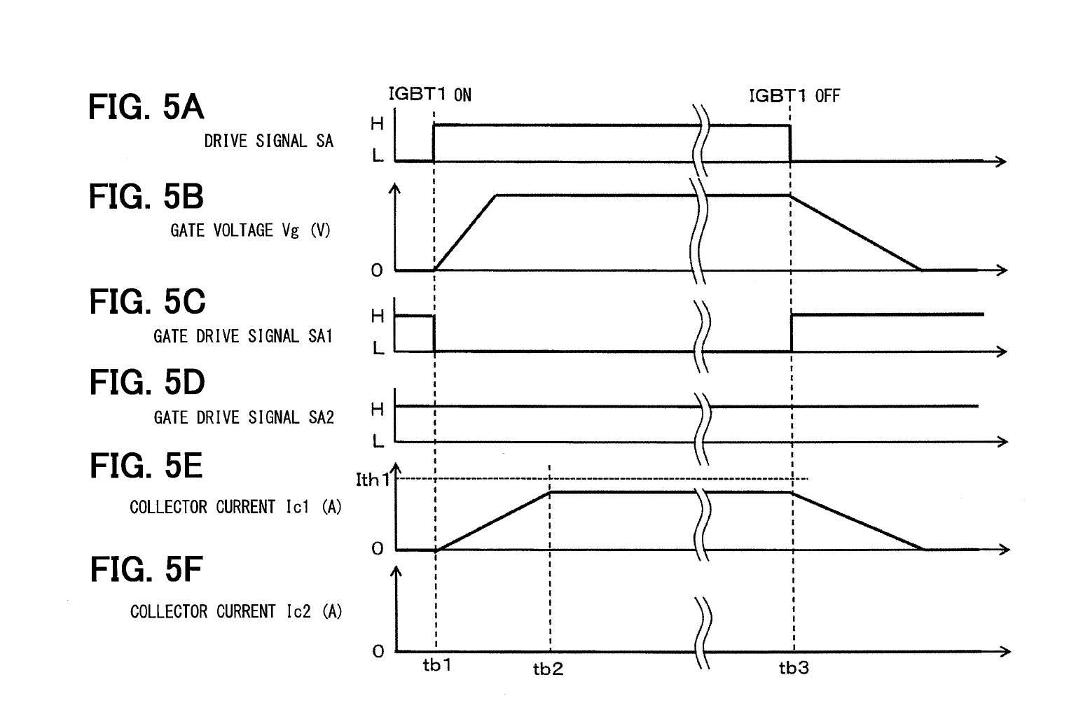

Next, the above operation will be described with reference to FIGS. 4A to 4F and FIGS. 5A to 5F. FIGS. 4A to 4F show a time chart in a case where a current flowing through a load (not shown) is large and both the IGBTs 1, 2 are turned on. FIGS. 5A to 5F show a time chart in a case where the current flowing through the load is small and only the IGBT 1 is turned on.

When the high-level drive signal SA is input at a time ta1 as shown in FIG. 4A, the control circuit 9 outputs the low-level gate drive signal SA1 for turning on the IGBT 1 as shown in FIG. 4C. Thereby, the gate-off switch 6 is turned off, the current cutoff switch 5 is turned on, and the gate drive voltage VG1 is applied from the constant current circuit 3 to the gate G1 of the IGBT 1 with the constant current Is.

As indicated by a solid line in FIG. 4B, a gate voltage Vg1 of the IGBT 1 rises with constant inclination by supplying the constant current Is to the gate G1, and as shown in FIG. 4E, a collector current Ic1 of the IGBT 1 increases gradually. After the gate voltage Vg1 of the IGBT 1 becomes a voltage equal to or higher than the predetermined level, the control circuit 9 switches the selector switch 4 to the on-state to invalidate the constant current circuit 3 and switch the state to the constant-voltage supply state.

Thereafter, when the collector current Ic1 of the IGBT 1 reaches the threshold current Ith1 at a time ta2 as shown in FIG. 4E, the control circuit 9 outputs a low-level gate drive signal SA2 as shown in FIG. 4D, to turn on IGBT 2. Thereby, the gate-off switch 8 is turned off, the current cutoff switch 7 is turned on, and the gate drive voltage VG2 is applied from the power source VD to the gate G2 of the IGBT 2 with a constant voltage.

As indicated by a broken line in FIG. 4B, a gate voltage Vg2 of the IGBT 2 rises with steeper inclination than the gate voltage vg1 of the IGBT 1 by applying the constant voltage to the gate G2, and as shown in FIG. 4F, a collector current Ic2 of the IGBT 2 increases. At this time, as shown in FIG. 4E, by the increase in the collector current Ic2 of the IGBT 2, the current shared by the collector current Ic1 of the IGBT 1 decreases and the collector current Ic1 becomes equal to or smaller than the threshold current Ith1. As a result, the power supply to the load is performed by the two IGBTs 1, 2.

Thereafter, as shown in FIG. 4F, when the rise of the collector current Ic2 of the IGBT 2 stops at a time ta3 and the collector current Ic2 becomes the constant current, the collector current Ic1 of the IGBT 1 also becomes the constant current, and the current flowing through the load as a whole is constant. Although this increases the switching loss at the time of turning on the IGBT 2, the sum of the losses due to the on-resistance by the two IGBTs 1, 2 decreases by an amount larger than the increase, so that the loss as a whole can be reduced.

Further, when the low-level drive signal SA for the turn-off operation from the outside is input into the control circuit 9 at a time ta4 as shown in FIG. 4A, the control circuit 9 outputs high-level gate drive signals SA1, SA2 as shown in FIGS. 4C and 4D. As a result, the current cutoff switches 5, 7 are turned off, the gate-off switches 6, 8 are turned on, the gate voltages Vg1, Vg2 of the IGBTs 1, 2 decrease, and the collector currents Ic1, Ic2 also decrease, to be shifted to the off-state.

Next, when the current flowing through the load is small and only the IGBT 1 is to be turned on, the operation as shown in FIG. 5A is performed. That is, when the high-level drive signal SA is input at a time tb1, the control circuit 9 outputs the low-level gate drive signal SA1 as shown in FIG. 5C, to turn on the IGBT 1. Thereby, the gate drive voltage VG1 is applied to the gate G1 of the IGBT 1 from the constant current circuit 3 by the constant current Is in the same manner as described above.

As indicated by a solid line in FIG. 5B, a gate voltage Vg1 of the IGBT 1 rises with constant inclination by supplying the constant current Is to the gate G1, and as shown in FIG. 5E, a collector current Ic1 of the IGBT 1 increases gradually After the gate voltage Vg1 of the IGBT 1 becomes a voltage equal to or higher than the predetermined level, the control circuit 9 switches the selector switch 4 to the on-state to invalidate the constant current circuit 3.

Thereafter, when the collector current Ic1 of the IGBT 1 reaches the constant current level at a time tb2 before reaching the threshold current Ith1, the IGBT 2 is not turned on, and the on-state of the IGBT 1 alone is held by the control circuit 9. Therefore, in this state, the control circuit 9 holds the gate drive signal SA2 at the high level as shown in FIG. 5D, and the collector current Ic2 of the IGBT 2 remains in a zero-state as shown in FIG. 5F.

The loss due to the turn-on operation of the IGBT 1 in this state is the sum of the switching loss and the on-resistance loss, but at the level of the current flowing through the load, namely, the collector current Ic1 of the IGBT 1, the loss can be reduced as compared with the case where the IGBT 2 is also turned on.

Thereafter, when the low-level drive signal SA for turn-off operation is input into the control circuit 9 from the outside at a time tb3 as shown in FIG. 5A, the control circuit 9 outputs the high-level gate drive signal SA1 as shown in FIG. 5C. As a result, the current cutoff switch 5 is turned off, the gate-off switch 6 is turned on, the gate voltage Vg1 of the IGBT 1 decrease, and the collector current Ic1 also decreases, to be shifted the off-state.

Next, rotation operation by the control circuit 9 will be described. In the present embodiment, the current detection circuit 11 is also provided in the IGBT 2. Although not used in the drive control of the IGBTs 1, 2 described above, each time the drive signal SA is applied, the IGBT to be driven first is interchanged between the IGBTs 1, 2.

Therefore, when the drive signal SA is input from the outside the next time, the control circuit 9 first drives and controls the IGBT 2 so as to apply the gate drive voltage VG2 at the constant current Is. When the collector current Ic2 of the IGBT 2 reaches the threshold current Ith1, the control circuit 9 outputs the gate drive signal SA1 so as to turn on the IGBT 1 according to the current detection signal S2 input from the current detection circuit 11.

The rotation control as described above may be performed by interchanging and driving the IGBTs 1, 2 each time the drive signal SA is input, or may be set to switch the IGBTs 1, 2 by a counter or the like each time the drive signal SA is input a plurality of times. It is also possible to perform the rotation control not by the number of inputs of the drive signal SA but by another method.

By the control circuit 9 performing the rotation control of the IGBTs 1, 2 as described above, it is possible to bring the IGBTs 1, 2 into an averaged use state, thereby averaging the lives of the IGBTs 1, 2.

According to the present embodiment as described above, the IGBT 1 is driven with the constant current Is by the control circuit 9, and when the collector current Ic1 of the IGBT 1 reaches the current threshold value Ith1, the IGBT 2 is driven with the constant voltage VD, whereby the total value of the switching loss and the on-resistance loss can be reduced as compared with the case where only the IGBT 1 is driven or when the IGBTs 1, 2 are driven simultaneously.

Further, by changing the number of two IGBTs 1, 2 driven in accordance with the current flowing through the load, it is possible to perform the drive under a condition such that the sum of switching loss and on-resistance loss becomes small. In other words, by setting the threshold current Ith1 to such a level, the drive control can be performed by setting the above conditions.

In the above embodiment, it has been configured such that the current detection circuit 11 for detecting the collector current Ic2 of the IGBT 2 is provided on the premise of the rotation control of the IGBTs 1, 2 by the control circuit 9. However, when the IGBT 1 is exclusively used for starting, the current detection circuit 10 for the IGBT 1 may be provided and the current detection circuit 11 may not be provided.

The output timing of the drive signal SX to the selector switch 4 by the control circuit 9 has been set at the point in time when the gate voltage Vg1 of the IGBT 1 reaches a predetermined level. However, the output may also be performed prior to the time when the collector current Ic1 of the IGBT 1 reaches the threshold current Ith1 and the IGBT 2 is turned on.

### Second Embodiment

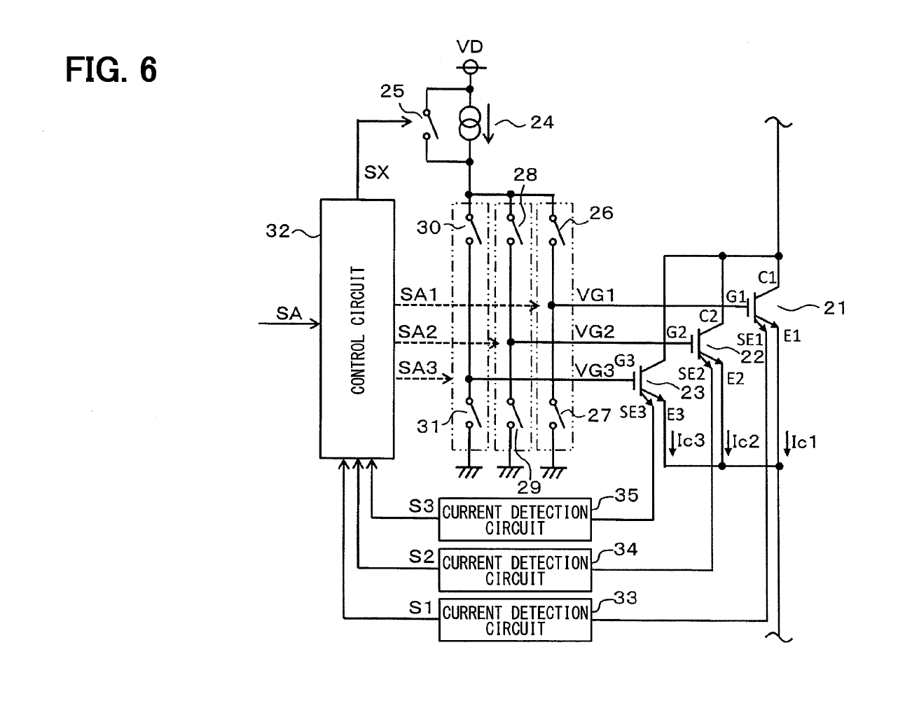

FIG. 6 to FIG. 11 show a second embodiment, and portions different from the first embodiment will be described below. In this embodiment, there is shown an example of a gate driving device applied to a configuration in which three IGBTs 21 to 23 are connected in parallel as a plurality of semiconductor elements.

FIG. 6 shows a schematic electrical configuration, in which the IGBTs 21 to 23 include collectors C1 to C3, emitters E1 to E3, and gates G1 to G3, respectively, and further include sense emitters SE1 to SE3 for monitoring current.

The IGBTs 21 to 23 are provided in a power supply path to a load (not shown), and have a configuration of a parallel drive system in which the collectors C1 to C3 are connected in common and the emitters E1 to E3 are connected in common. The gate drive voltages VG1 to VG3 to the three IGBTs 21 to 23 are configured to be supplied from the DC power source VD via a parallel circuit of a constant current circuit 24 and a selector switch 25.

The gate drive voltage VG1 is applied to the gate G1 of the IGBT 21 from the constant current circuit 24 via a gate current cutoff switch 26. Further, the gate G1 of the IGBT 21 is connected to the ground via a gate-off switch 27. The gate drive voltage VG2 is applied to the gate G2 of the IGBT 22 from the constant current circuit 24 via a gate current cutoff switch 28. Further, the gate G2 of the IGBT 22 is connected to the ground via a gate-off switch 29. The gate drive voltage VG3 is applied to the gate G3 of the IGBT 23 from the constant current circuit 24 via a gate current cutoff switch 30. Further, the gate G3 of the IGBT 23 is connected to the ground via a gate-off switch 31.

A control circuit 32 is constituted of a logic circuit including a gate drive circuit, and the like and applies gate drive signals SA1 to SA3 to the IGBTs 21 to 23 according to the drive signal SA from the outside. Current detection circuits 33 to 35 respectively receive inputs of signals corresponding to collector-emitter currents Ic1 to Ic3 from the sense emitters SE1 to SE3 of the IGBTs 21 to 23, and output current detection signals S1 to S3 to the control circuit 32. In accordance with the current detection signals S1 to S3, the control circuit 32 performs on/off control of the selector switch 25, the current cutoff switches 26, 28, 30 and the gate-off switches 27, 29, 30 in a manner as described later.

Although the description of a specific circuit configuration having the above configuration will be omitted, a circuit configuration substantially equivalent to that of the first embodiment shown in FIG. 2 is provided corresponding to the three IGBTs 21 to 23. In this embodiment, the current detection circuits 33 to 35 determine the levels of the collector currents Ic1 to Ic3 with two threshold currents of threshold currents Ith1, Ith2, respectively. As the current detection signals S1 to S3, signals corresponding to the respective detection levels are output.

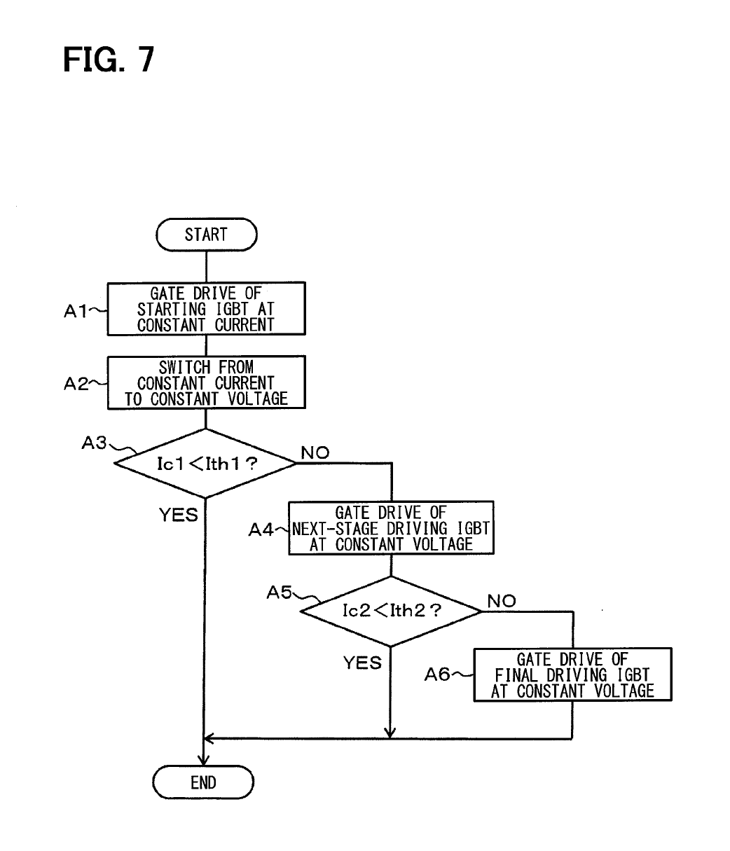

Next, the operation of the above configuration will be described also with reference also to FIGS. 7 to 11.

FIG. 7 shows a flow of the gate drive control operation of the IGBTs 21 to 23 by the logic function of the control circuit 32. In a standby state, the control circuit 32 outputs a low-level signal SX that holds the off-state to the selector switch 25, whereby the power source VD allows the constant current Is generated in the constant current circuit 24 to flow to supply the gate drive voltages VG1 to VG3.

In a state where the IGBTs 21 to 23 are not driven, the control circuit 32 outputs high-level gate drive signals SA1 to SA3 to the IGBTs 21 to 23. Thereby, the current cutoff switches 26, 28, 30 are held in the off-state, and the gate-off switches 27, 29, 31 are held in the on-state. The respective gates G1 to G3 of the IGBTs 21 to 23 are connected to the ground via the gate-off switches 27, 29, 31, and are held in the off-state.

When the high-level drive signal SA is applied from the outside, the control circuit 32 drives the IGBT 21, which is the start-up semiconductor element, with a constant current as step A1 in the same manner as in the first embodiment. Thereafter, when the gate voltage of the IGBT 21 becomes stable, the control circuit 32 outputs a low-level switching signal SX to the selector switch 25 in step A2 to stop the constant-current supply state by the constant current circuit 24 to be switched to a constant-voltage supply state for directly supplying the power source VD.

Upon detecting that the current value Ic1 of the IGBT 21 becomes equal to or greater than the threshold current Ith1, the current detection circuit 33 outputs the detection signal S1 to the control circuit 32. When the current value Ic1 of the IGBT 21 is in a state smaller than the threshold current Ith1, the control circuit 32 maintains the on-state of the IGBT 21 alone as YES in step A3. Further, when the current value Ic1 becomes equal to or greater than the threshold current Ith1 and the detection signal S1 reaching or exceeding the threshold current Ith1 from the current detection circuit 33 is output, the control circuit 32 proceeds to step A4 and drives the IGBT 22 at a constant voltage.

At this time, since the voltage applied across the drain and the source is in already low state because the IGBT 21 is already on, the IGBT 22 can reduce the loss by being drive at a constant voltage. In addition, by driving the two IGBTs 21, 22, the entire current can be allowed to flow in a state where the on-resistance has been reduced as a whole, and the on-resistance loss can be reduced.

In this state, when the current detection circuit 34 detects that the current value Ic2 of the IGBT 22 becomes equal to or greater than the threshold current Ith2, the current detection circuit 34 outputs the detection signal S2 to the control circuit 32. When the current value Ic2 of the IGBT 22 has not reached the threshold current Ith2, the control circuit 32 continues the on-state of the IGBTs 21, 22 as YES in step A5. When the current value Ic2 becomes equal to or greater than the threshold current Ith2 and the detection signal S2 reaching or exceeding the threshold current Ith2 is output from the current detection circuit 34, the control circuit 32 proceeds to step A6, and further drives the IGBT 23 at a constant voltage.

At this time, since the voltage applied across the drain and the source is low in the IGBT 23 because the IGBTs 21, 22 are already on, the loss can be reduced by performing the constant voltage drive. In addition, by driving the three IGBTs 21 to 23, it is possible to allow the entire current to flow in a state where the on-resistance is reduced as a whole, and reduce the on-resistance loss.

In the above operation, the value of the threshold current Ith1 of the current detection circuit 33 is set to such a level that, when a collector current Ic1 of the IGBT 21 further increases, the loss due to the on-resistance of the IGBT 21 increases, and even when the IGBT 22 is also driven to increase the switching loss, the loss due to the on-resistance is reduced, to enable reduction in loss as whole.

The value of the threshold current Ith2 of the current detection circuit 34 is set to such a level that, when the collector current Ic2 of the IGBT 22 further increases, the loss due to the on-resistance of the IGBTs 21, 22 increases, and even when the IGBT 23 is also driven to increase the switching loss, the loss due to the on-resistance is reduced, to enable reduction in loss as whole.

Thereby, in order to reduce variations in switching loss at the time of initial driving, the IGBT 21 is driven with a constant current, and when the current Ic1 of the IGBT 21 becomes equal to or greater than the threshold current Ith1, the IGBT 22 being the next-stage driving semiconductor element is driven with a constant voltage, so that the on operation where dV/dt is raised to reduce the loss can be performed. Further, when the current Ic2 of the IGBT 22 becomes equal to or greater than the threshold current Ith2, the IGBT 23 being the next-stage driving and final-stage driving semiconductor element is driven with a constant voltage, so that the on operation where dV/dt is raised to reduce the loss can be performed.

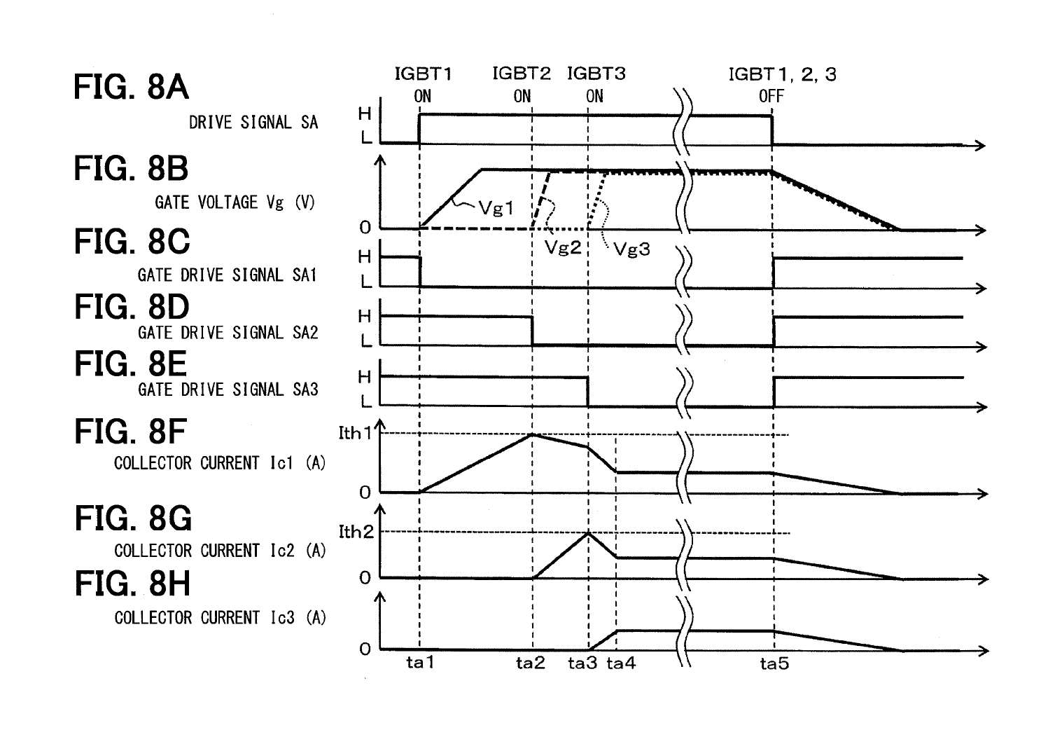

Next, the above operation will be described with reference to FIGS. 8A to 8H to FIGS. 10A to 10H.

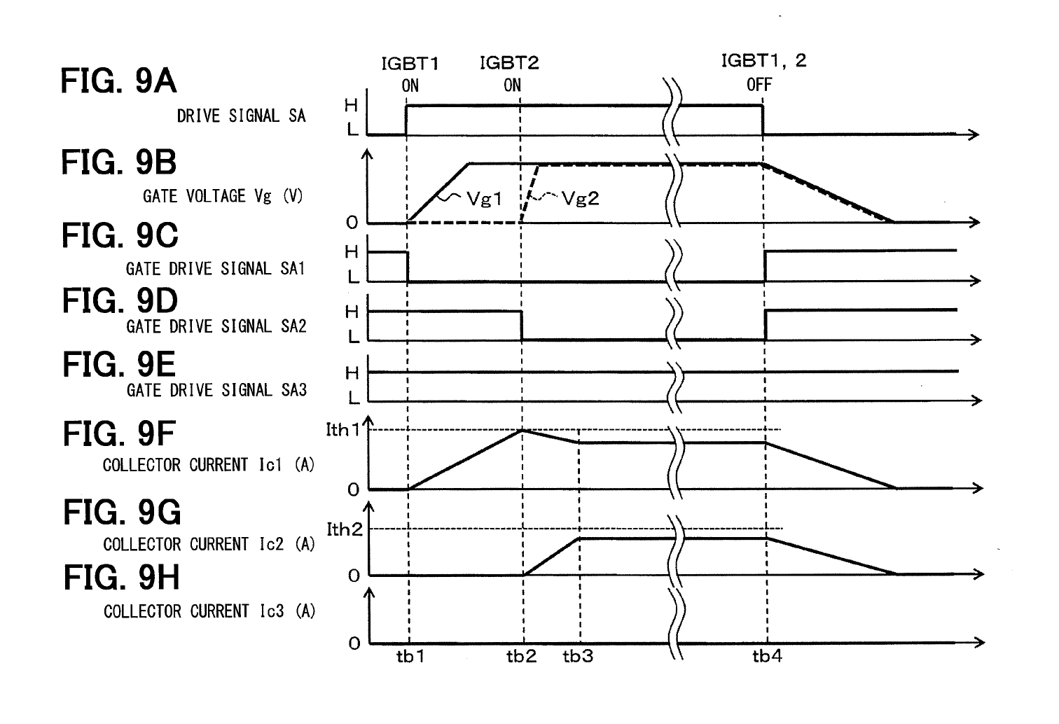

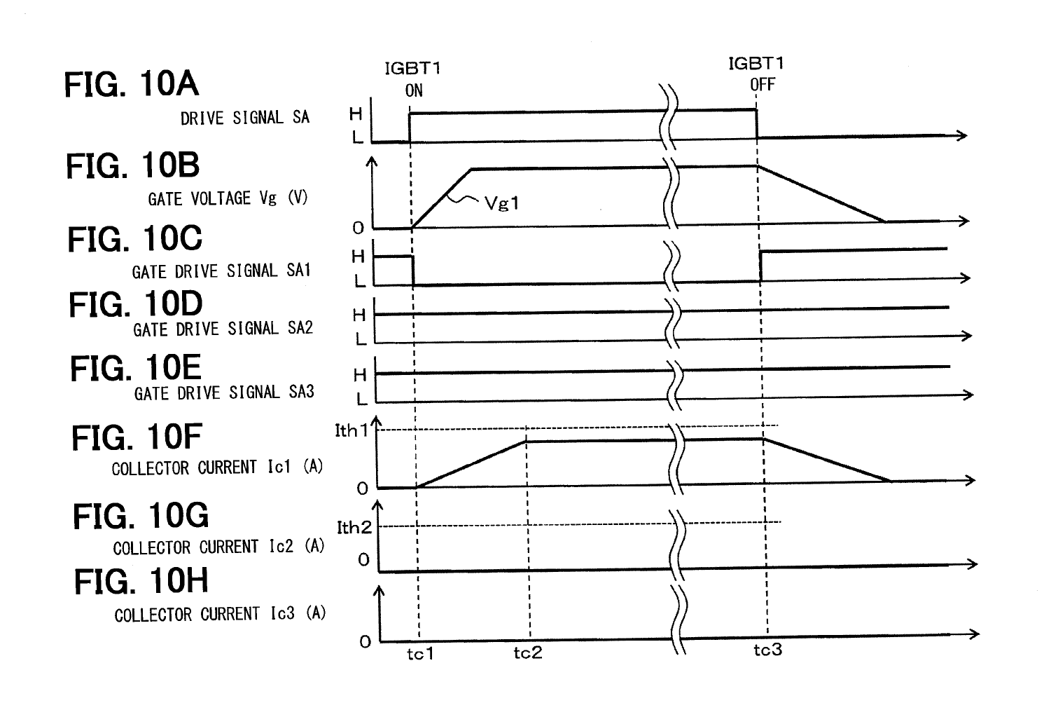

FIGS. 8A to 8H show a time chart in a case where the current flowing through the load is large and the three IGBTs 21 to 23 are turned on together. Further, FIGS. 9A to 9H show a time chart in a case where the current flowing through the load is medium and the IGBTs 21, 22 are turned on. FIGS. 10A to 10H show a time chart in a case where the current flowing through the load is small and only the IGBT 21 is turned on.

When the high-level drive signal SA is input at a time ta1 as shown in FIG. 8A, the control circuit 32 outputs the low-level gate drive signal SA1 for turning on the IGBT 21 as shown in FIG. 8C. Thereby, the gate-off switch 27 is turned off, the current cutoff switch 26 is turned on, and the gate drive voltage VG1 is supplied from the constant current circuit 24 to the gate G1 of the IGBT 21 by the constant current Is.

As indicated by a solid line in FIG. 8B, a gate voltage Vg1 of the IGBT 21 rises with constant inclination by supplying the constant current Is to the gate G1, and as shown in FIG. 8F, a collector current Ic1 of the IGBT 21 increases gradually. After the gate voltage Vg1 of the IGBT 21 becomes a voltage equal to or higher than the predetermined level, the control circuit 32 switches the selector switch 25 to the on-state to invalidate the constant current circuit 24.

Thereafter, when the collector current Ic1 of the IGBT 21 reaches the threshold current Ith1 at a time ta2, as shown in FIG. 8D, the control circuit 32 outputs a low-level gate drive signal SA2 to turn on IGBT 22. Thereby, the gate-off switch 29 is turned off, the current cutoff switch 28 is turned on, and the gate drive voltage VG2 is applied from the power source VD to the gate G2 of the IGBT 22 with a constant voltage.

As indicated by a broken line in FIG. 8B, a gate voltage Vg2 of the IGBT 22 rises with steeper inclination than the gate voltage vg1 of the IGBT 21 by applying the constant voltage to the gate G2, and as shown in FIG. 8G, a collector current Ic2 of the IGBT 22 increases. At this time, the collector current Ic1 of the IGBT 21 becomes equal to or lower than the threshold current Ith1 because the current shared by the collector current Ic1 of the IGBT 21 decreases by the increase in the collector current Ic2 of the IGBT 22. As a result, the power supply to the load is performed by the two IGBTs 21, 22

Thereafter, when the collector current Ic2 of the IGBT 22 reaches the threshold current Ith2 at a time ta3, as shown in FIG. 8E, the control circuit 32 outputs a low-level gate drive signal SA3 to turn on IGBT 23. Thereby, the gate-off switch 31 is turned off, the current cutoff switch 30 is turned on, and the gate drive voltage VG3 is applied from the power source VD to the gate G3 of the IGBT 23 with a constant voltage.

As indicated by a dotted line in FIG. 8B, similarly to the gate voltage Vg2 of the IGBT 22, a gate voltage Vg3 of the IGBT 23 rises with steep inclination by applying the constant voltage to the gate G3, and as shown in FIG. 8H, a collector current Ic3 of the IGBT 23 increases. At this time, by the increase in the collector current Ic3 of the IGBT 23, the current shared by the collector currents Ic1, Ic2 of the IGBTs 21, 22 decreases and the collector current Ic2 becomes equal to or smaller than the threshold current Ith2. As a result, the power supply to the load is performed by the three IGBTs 21 to 23.

Thereafter, when the rise of the collector current Ic3 of the IGBT 23 stops at a time ta4 and the collector current Ic3 becomes the constant current, the collector currents Ic1, Ic2 of the IGBTs 21, 22 also become the constant current, and the current flowing through the load as a whole becomes constant. Although this increases the switching loss at the time of turning on the IGBTs 22, 23, the sum of the losses due to the on-resistance by the three IGBTs 21 to 23 decreases by an amount larger than the increase, so that the loss as a whole can be reduced.

Further, when the low-level drive signal SA for the turn-off operation from the outside is input into the control circuit 32 at a time ta5 as shown in FIG. 8A, the control circuit 32 outputs high-level gate drive signals SA1 to SA3 as shown in FIGS. 8C to 8E. As a result, the current cutoff switches 26, 28, 30 are turned off, the gate-off switches 27, 29, 31 are turned on, the gate voltages Vg1 to Vg3 of the IGBTs 21 to 23 decrease, and the collector currents Ic1 to Ic3 also decrease, to be shifted to the off-state.

Next, when the current flowing through the load is medium and the IGBTs 21, 22 are to be turned on, the operation as shown in FIGS. 9A to 9H is performed. This operation is the same as the operation in the case shown in FIG. 4 described in the first embodiment, and hence the description will be omitted. Similarly, when the current flowing through the load is small and only the IGBT 21 is to be turned on, the operation as shown in FIGS. 10A to 10H is performed. This operation is also equivalent to the operation in the case shown in FIGS. 5A to 5F described in the first embodiment, and hence the description will be omitted.

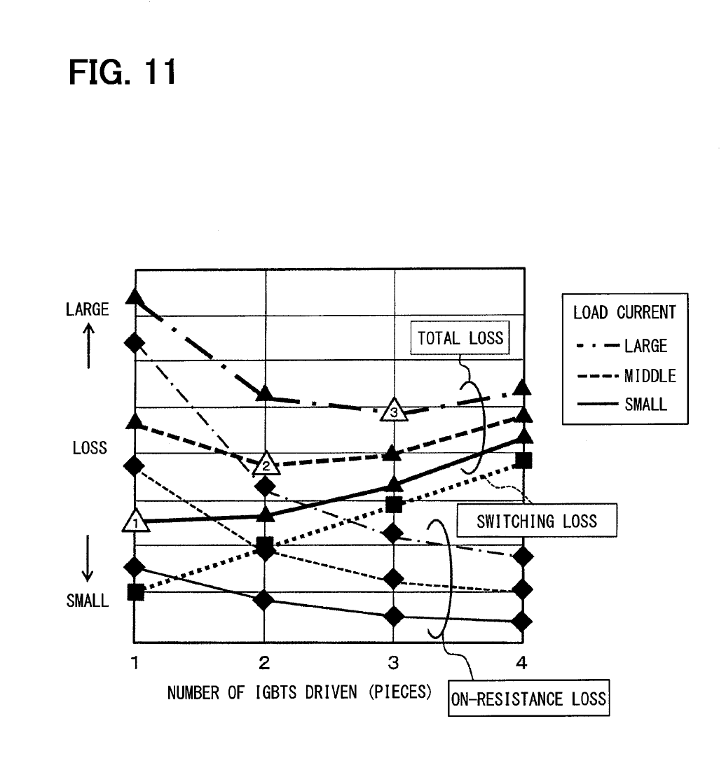

Next, the relationship between the above operation and occurrence of loss will be described with reference to FIG. 11. In the present embodiment, the three IGBTs 21 to 23 are configured to control the turn-on operation according to the magnitude of the load current. In this case, the relationship between the number of IGBTs 21 to 23 to be turned on and the switching loss, on-resistance loss, and total loss that occur at that time is shown.

Regarding the switching loss, the loss per IGBT is somewhat smaller by the constant current drive, and the losses that occur by the constant voltage drive after the constant current drive are almost the same. Therefore, as indicated by black squares and dotted lines in the figure, they show a tendency to increase substantially in proportion to the number of IGBTs to be turned on.

On the other hand, the on-resistance loss differs according to the current level of the load current, and the loss is shown corresponding to the case of the load current being “large”, “medium”, or “small.” The case where the three IGBTs 21 to 23 described above are turned on is indicated by black squares and solid lines with the load current being “large” The case where the two IGBTs 21, 22 are turned on is indicated by black squares and broken lines with the load current being “medium.” The case where only the IGBT 21 is turned on is indicated by a black square and a one-dot chain line with the load current being “small.” The on-resistance loss tends to decrease as the number of turn-on operations of the IGBT increases at any load current level.

The total loss in the case of turning on the IGBTs 21 to 23 is the sum of the switching loss and the on-resistance loss. The total loss is indicated by a heavy solid line, heavy dashed line, thick dotted chain line, and black triangle according to the current level “large”, “middle”, and “small” of the load current in the figure. It can thus be said that the number of IGBTs driven when the total loss is the smallest is a suitable drive control state.

As a result, when the load current is “large”, the total loss at the time of turning on the three IGBTs 21 to 23 with “3” put down in an open triangle is the smallest. When the load current is “medium”, the total loss at the time of turning on the two IGBTs 21, 22 with “2” put down in an open triangle is the smallest. When the load current is “small”, the total loss at the time of turning on the one IGBT 21 with “1” put down in an open triangle is the smallest.

In other words, by setting the threshold currents Ith1, Ith2 so that the number of IGBTs 21 to 23 to be driven is switched depending on the level of the load current as described above, it is possible to minimize the total loss caused by the level of the load current.

Since the current detection circuits 33 to 35 are provided corresponding to the respective IGBTs 21 to 23 also in the above configuration, similarly to the first embodiment, the drive control can be performed by the rotation operation of the IGBTs 21 to 23 by the control circuit 32.

The rotation control by the control circuit 32 may be performed by appropriately interchanging and driving the IGBTs 21 to 23 each time the drive signal SA is input, or may be set to switch the IGBTs 21 to 23 by a counter or the like each time the drive signal SA is input a plurality of times. It is also possible to perform the rotation control not by the number of inputs of the drive signal SA but by another method.

By the control circuit 32 performing the rotation control of the IGBTs 21 to 23 as described above, it is possible to bring the IGBTs 21 to 23 into an averaged use state, thereby averaging the lives of the IGBTs 21 to 23.

Therefore, the same operation and effect as in the first embodiment can be obtained also by the second embodiment as thus described, even when the three IGBTs 21 to 23 are provided.

In the above embodiment as well, it has been configured such that the current detection circuit 35 for detecting the collector current Ic3 of the IGBT 23 is provided on the premise of the rotation control of the IGBTs 21 to 23 by the control circuit 32. However, the rotation operation can be performed on the two IGBTs 21, 22 as a configuration where the current detection circuit 35 is not provided.

### Third Embodiment

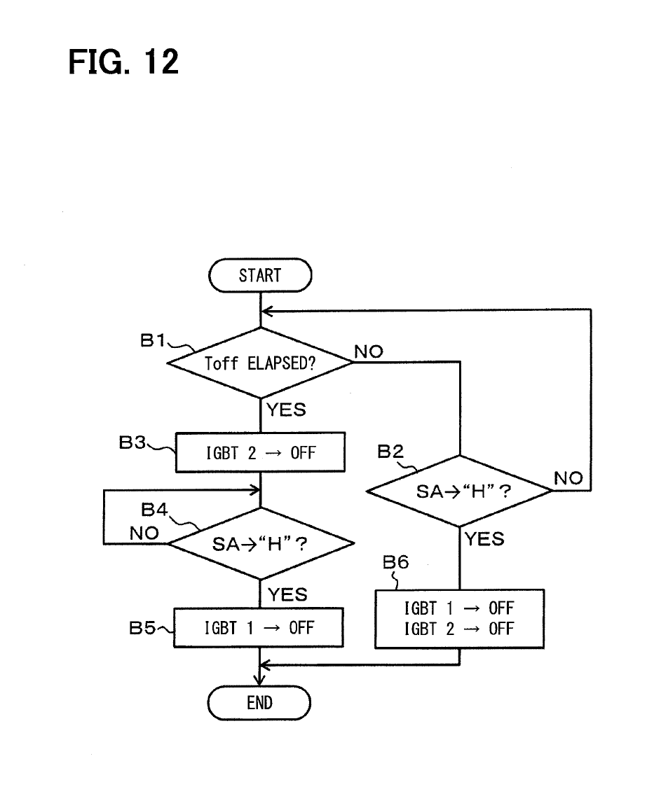

FIGS. 12 to 14 show a third embodiment, and portions different from the first embodiment will be described below. In this embodiment, there is shown a control in the case of turning off the IGBTs 1, 2 in a state where IGBTs 1, 2 are both turned on in the same configuration as the above-described first embodiment. In this embodiment, the case is shown where the two IGBTs 1, 2 are turned on simultaneously as to the turn-on operation in order to show the control based on the turn-off operation. However, as a matter of course, it is possible to control the turn-on operation as in the first embodiment.

FIG. 12 shows the flow of the control operation at the time when the IGBTs 1, 2 are driven to be turned off during the turn-on operation by the control circuit 9. In this embodiment, the off-time toff of the IGBT 2 to be turned off beforehand is set in advance in a case where an on-period Ton by the externally applied drive signal SA is set to fall within a certain range.

When the high-level drive signal SA for the turn-on operation from the outside is input from the outside, the control circuit 9 starts counting the elapsed time from that point in time. The control circuit 9 performs the operation shown in FIG. 12 when the two IGBTs 1, 2 are turned on. That is, the control circuit 9 firstly determines whether or not the drive signal SA has changed to the low level indicating the turn-off operation in step B, while waiting for the elapsed time to pass the off-time toff as step B1.

In a normal case, the off-time toff elapses first, and hence the control circuit 9 outputs the high-level gate drive signal SA2 so as to first turn off the IGBT 2 as step B3. Thereby, the IGBT 2 is turned off while the IGBT 1 is held in the on-state. Thereafter, in step B4, the control circuit 9 waits for input of the low-level drive signal SA from the outside, and in step B5, the control circuit 9 turns off the IGBT 1, to complete the operation.

On the other hand, when the low-level drive signal SA is input from the outside before the off-time toff elapses, the control circuit 9 becomes YES in step B2, and then turns off both the two IGBTs 1, 2 in step B6.

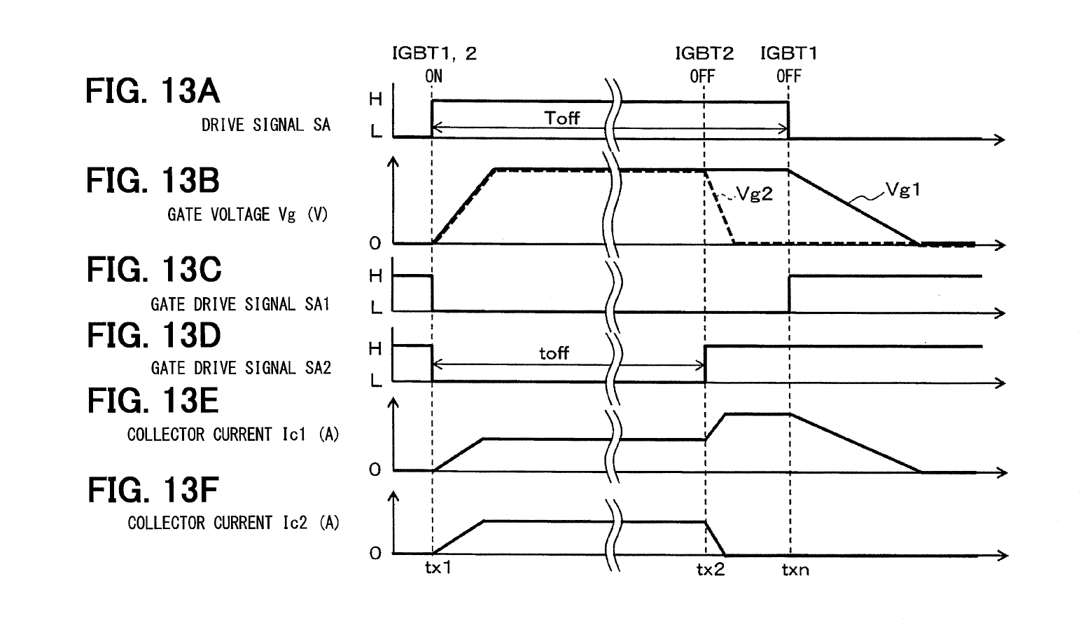

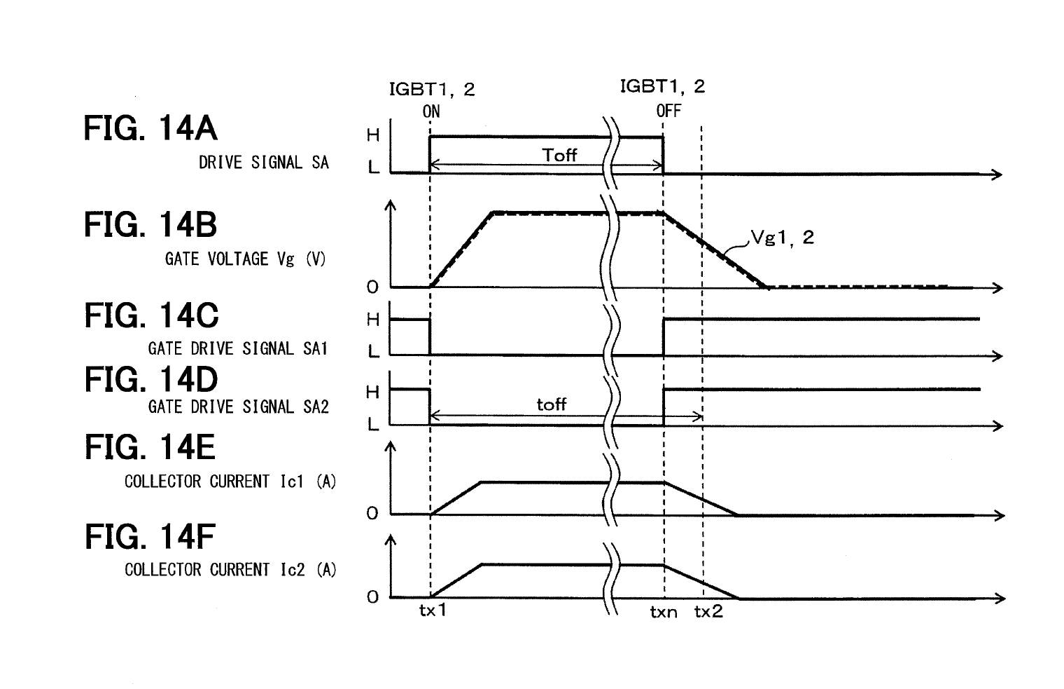

Next, the turn-off operation will be described with reference to FIGS. 13A to 13F and FIGS. 14A to 14F. FIGS. 13A to 13F show a time chart in the case where the off-period toff elapses before the low-level drive signal SA is input after the turn-on operation of the two IGBTs 1, 2. FIGS. 14A to 14F show a time chart in a case where the low-level drive signal SA is input before the off-period toff elapses after the turn-on operation of the two IGBTs 1, 2.

First, in the operations of FIGS. 13A to 13F, when the high-level drive signal SA is input at a time tx1 as shown in FIG. 13A, the control circuit 9 outputs the low-level gate drive signals SA1, SA2 for turning on the IGBTs 1, 2 as shown in FIGS. 13C, 13D. Thereby, the gate-off switches 6, 8 are turned off, the current cutoff switches 5, 7 are turned on, and the gate drive voltages VG1, VG2 are applied from the constant current circuit 3 to the gate G1, G2 of the IGBTs 1, 2 by the constant current Is.

The gate voltages Vg1, Vg2 of the IGBTs 1, 2 are raised with constant inclination by supplying the constant current Is to the gates G1, G2 as indicated by a solid line and a broken line in FIG. 13B, and as shown in FIGS. 13E and 13F the collector currents Ic1, Ic2 of the IGBTs 1, 2 gradually increase to come into the on-state. Thereafter, the control circuit 9 switches the selector switch 4 to the on-state to invalidate the constant current circuit 3.

Thereafter, when the off-period toff elapses at a time tx2 during the turn-on operation of the IGBTs 1, 2, the control circuit 9 outputs the high-level gate drive signal SA2 as shown in FIG. 13D, to turn off the IGBT 2. The gate voltage Vg2 of the IGBT 2 drops to zero as shown in FIG. 13B, and the collector current Ic2 also drops to zero as shown in FIG. 13F. At this time, as shown in FIG. 13E, the collector current Ic1 of the IGBT 1 is increased by addition of the collector current Ic2 having flown through the IGBT 2.

Thereafter, when the low-level drive signal SA is input from the outside at a time txn as shown in FIG. 13A, the control circuit 9 outputs the high-level gate drive signal SA1 as shown in FIG. 13C, to turn off the IGBT 1. The gate voltage Vg1 of the IGBT 1 gradually decreases as shown in FIG. 13B, and the collector current Ic1 also drops to zero as shown in FIG. 13E.

As a result, for the two IGBTs 1, 2 in the turn-on operation, the IGBT 1 is turned off after the IGBT 2 is turned off at the point in time when timer time toff elapses beforehand, so that it is possible to reduce the switching off loss such as heat generation caused by a tail current during the off-drive as compared to the case where the two IGBTs 1, 2 are turned off simultaneously.

In the above operation, the IGBT 2 can be turned off first because the off-period toff is set to elapse before the lapse of the period Toff to the input of the low-level drive signal SA from the outside. However, the operation shown in FIGS. 14A to 14F is performed assuming that the low-level drive signal SA instructing the turn-off operation is input before the lapse of the period Toff.

That is, in FIGS. 14A to 14F, as shown in FIG. 14A, when the two IGBTs 1, 2 are in the on-state and the low-level drive signal SA is input from the outside at a time txn before the time tx2 at which the off-period toff elapses, the control circuit 9 outputs high-level gate drive signals SA1, SA2 as shown in FIGS. 14C and 14D. Thereby, the gate voltages Vg1, Vg2 of the two IGBTs 1, 2 drop to zero as shown in FIG. 14B, and the collector currents Ic1, Ic2 becomes zero as shown in FIGS. 14E and 14F, to turn off the IGBTs 1, 2.

According to the third embodiment, the IGBT 1 is turned off at the timing of the drive signal SA after the IGBT 2 is turned off earlier by the control circuit 9 at the lapse point of the off-time toff, so that it is possible to reduce the switching off loss such as heat generation caused by a tail current during the off-drive.

Although the above embodiment is the case of using the two IGBTs 1, 2, the present invention can also be applied to the second embodiment where three IGBTs are provided or to a configuration where four or more IGBTs are provided. In this case, one IGBT to be turned off last can be left and the remaining IGBTs can be turned off simultaneously.

### Fourth Embodiment

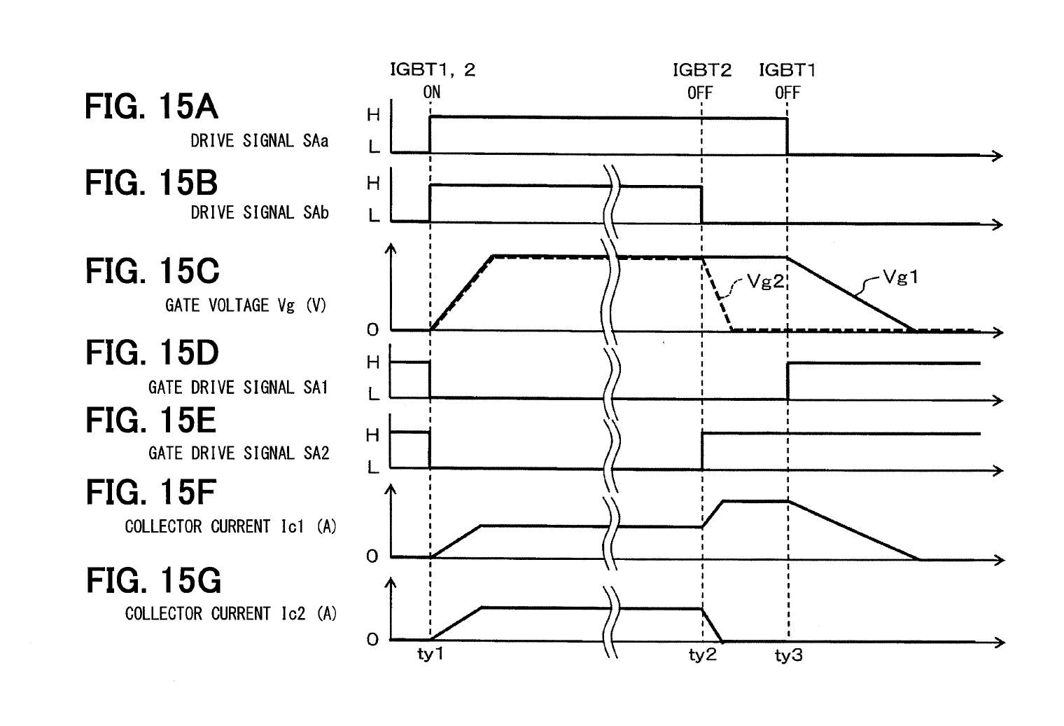

FIGS. 15A to 15G show a fourth embodiment, and different portions from the third embodiment will be described. In this embodiment, it is configured such that, as for the gate drive signal to be applied to the control circuit 9, a drive signal SAb for turning-off is applied before a drive signal SAa for final turning-off.

When the control circuit 9 turns on the two IGBTs 1, 2 at a time ty1 in the same manner as described above, the low-level drive signal SAb is then input from the outside at a time ty2 as shown in FIG. 15B. Thereby, as shown in FIG. 15E, the control circuit 9 outputs a high-level gate drive signal SA2 to turn off the IGBT 2. The gate voltage Vg2 of the IGBT 2 drops to zero as shown in FIG. 15C, and the collector current Ic2 also drops to zero as shown in FIG. 13G. At this time, as shown in FIG. 1fE, the collector current Ic1 of the IGBT 1 is increased by addition of the collector current Ic2 having flown through the IGBT 2.

Thereafter, when the low-level drive signal SAa is input from the outside at a time ty3 as shown in FIG. 15A, the control circuit 9 outputs the high-level gate drive signal SA1 as shown in FIG. 1_{d}C, to turn off the IGBT 1. The gate voltage Vg1 of the IGBT 1 gradually decreases as shown in FIG. 15B, and the collector current Ic1 also drops to zero as shown in FIG. 15E.

As a result, the IGBT 2 is turned off and then the IGBT 1 is turned off by the drive signals SAa, SAb that are input to the two IGBTs 1, 2 being turned on at different timings, so that the same effect as in the third embodiment can be obtained.

In this embodiment as well, as in the third embodiment, the present invention can also be applied to the second embodiment where three IGBTs are provided or to a configuration where four or more IGBTs are provided.

### Fifth Embodiment

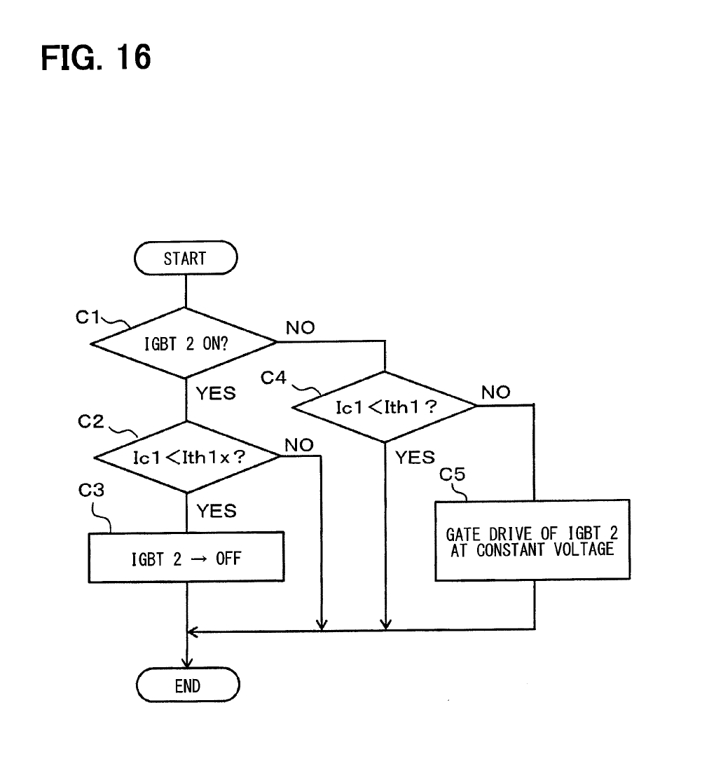

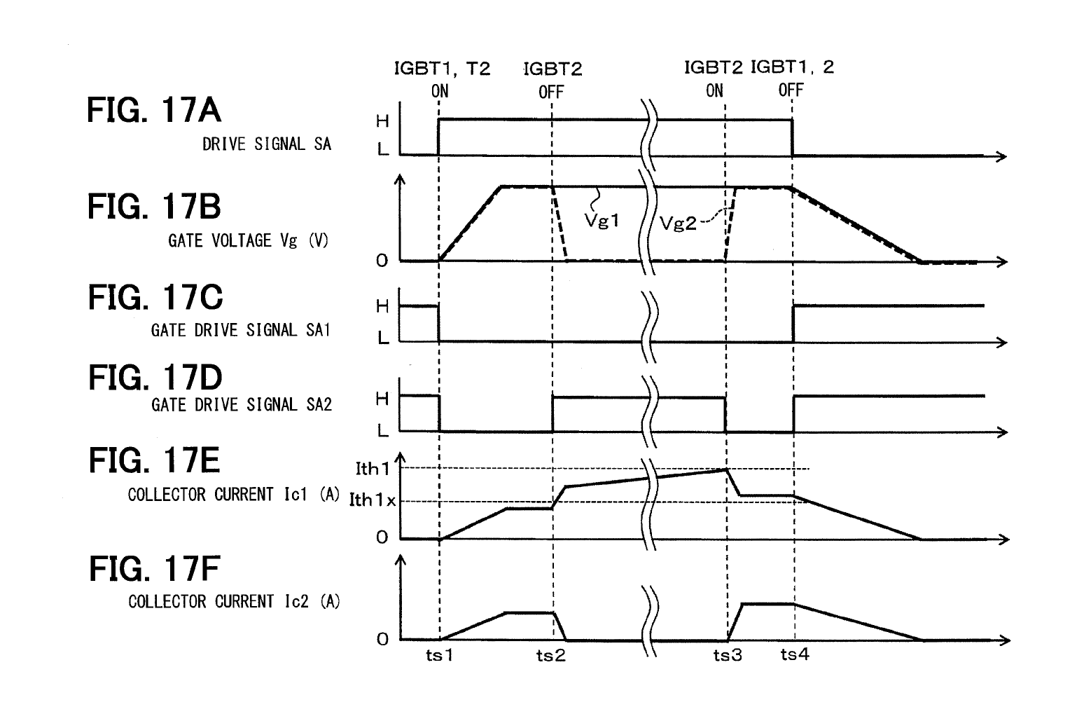

FIGS. 16 and 17 show a fifth embodiment, and portions different from the first embodiment will be described below. The electrical configuration is the same as that shown in FIGS. 1 and 2 shown in the first embodiment. This embodiment shows the operation in a case of variations in the collector current Ic1 in a state where a plurality of IGBTs 1, 2 are driven together or in a state where one thereof is driven. In this embodiment, a case is shown where the two IGBTs 1, 2 are turned on simultaneously as to the turn-on operation in order to show the control based on the turn-off operation. However, as a matter of course, it is possible to control the turn-on operation as in the first embodiment.

FIG. 16 shows the flow of the control operation on the IGBTs 1, 2 during the turn-on operation by the control circuit 9 in a case where the turn-off operation of the IGBT2 is controlled while the collector current Ic1 of the IGBT 1 is detected, or a case where the IGBT 2 is turned on after being turned off.

The control circuit 9 receives input of the high-level drive signal SA for the turn-on operation from the outside and drives the IGBTs 1, 2, and thereafter starts the operation of the gate drive control shown in FIG. 16. The control circuit 9 first determines whether or not the IGBT 2 has currently been turned on as step C1, and since the IGBTs 1, 2 have been turned on at the initial stage, the control circuit 9 proceeds to step C2 as YES.

In step C2, the control circuit 9 determines whether or not the level of the collector current Ic1 of the IGBT 1 is a level at which a single turn-on operation is possible as a determination level, based on the off-level threshold current Ith1x. The off-level threshold current Ith1x has been set, for example, to equal to or smaller than about one half of the threshold current Ith1 described above. Thus, in the case of YES here, the control circuit 9 turns off the IGBT 2 in step C3. Thereby, a collector current obtained by adding the collector currents Ic1, Ic2 shared by the two IGBTs 1, 2 flows through the IGBT 1, but the collector current Ic1 at this time has a level not exceeding the threshold current Ith1.

In the case of NO in step C2, namely, when the collector current Ic1 of the IGBT 1 is not lower than the off-level threshold current Ith1x, the control circuit 9 holds the IGBT 2 in the on-state. Hereinafter, in a state where the two IGBTs 1, 2 are driven, the control circuit 9 repeatedly executes the above-described steps.

Next, in a state where the IGBT 1 is driven alone, the control circuit 9 determines NO in step C1 and proceeds to step C4 to determine whether or not the collector current Ic1 of the IGBT 1 falls below the threshold current Ith1. When the collector current Ic1 has not increased from the above state, the control circuit 9 determines YES in step C4 and comes into the state of no action.

On the other hand, when the collector current Ic1 of the IGBT 1 is increased to be equal to or greater than the threshold current Ith1, the control circuit 9 determines NO in step C4 and proceeds to step C5, where the IGBT 2 is driven with a constant voltage. Thereafter, the control circuit 9 repeats the above-described gate drive control until the off signal is given to the IGBT 1, 2 as the signal SA from the outside.

Next, an example of the above gate drive control will be described with reference to FIGS. 17A to 17F. FIGS. 17A to 17F are a time chart in a case where the gate drive control is performed according to the change in the collector current Ic1 of the IGBT 1 after simultaneous turn-on operation of the two IGBTs 1, 2.

As shown in FIG. 17A, when the high-level drive signal SA is input at a time ts1, the control circuit 9 outputs low-level gate drive signals SA1, SA2 to turn on the IGBTs 1, 2 as shown in FIGS. 17C and 17D. Thereby, the gate-off switches 6, 8 are turned off, the current cutoff switches 5, 7 are turned on, and the gate drive voltages VG1, VG2 are applied from the constant current circuit 3 to the gate G1, G2 of the IGBTs 1, 2 by the constant current Is.

The gate voltages Vg1, Vg2 of the IGBTs 1, 2 are raised with constant inclination by supplying the constant current Is to the gates G1, G2 as indicated by a solid line and a broken line in FIG. 17B, and as shown in FIGS. 17E and 17F, the collector currents Ic1, Ic2 of the IGBTs 1, 2 gradually increase to come into the on-state. Thereafter, the control circuit 9 switches the selector switch 4 to the on-state to invalidate the constant current circuit 3.

Thereafter, when the level of the collector current Ic1 of the IGBT 1 does not become equal to or higher than the off-level threshold current Ith1x during the turn-on operation of the IGBTs 1, 2, the control circuit 9 turns off the IGBT 2 at a time tx2. Thereby, a collector current obtained by adding the collector currents Ic1, Ic2 shared by the two IGBTs 1, 2 flows to the IGBT 1.

Thereafter, when the collector current Ic1 flowing through the IGBT 1 gradually increases and reaches or exceeds the threshold current Ith1 at a time ts3, the control circuit 9 drives the IGBT 2 at a constant voltage. Thereby, a part of the collector current Ic1 flowing through the IGBT 1 flows as the collector current Ic2 of the IGBT 2, and the collector current Ic1 of the IGBT 1 becomes smaller than the threshold current Ith1.

Such gate drive control is repeatedly executed by the control circuit 9, and in response to the change in the current flowing through the load, the drive control is performed so that the IGBTs 1, 2 do not exceed the threshold current Ith1.

According to the fifth embodiment, the control circuit 9 turns off the IGBT 2 during the turn-on operation of the two IGBTs 1, 2 and turns on the IGBT 2 at a constant voltage during the turn-on operation of one IGBT 1, whereby it is possible to obtain the same effect as in the first embodiment even during the operation of the IGBTs 1, 2.

Although the above embodiment is the case of using the two IGBTs 1, 2, the present invention can also be applied to the second embodiment where three IGBTs are provided or to a configuration where four or more IGBTs are provided.

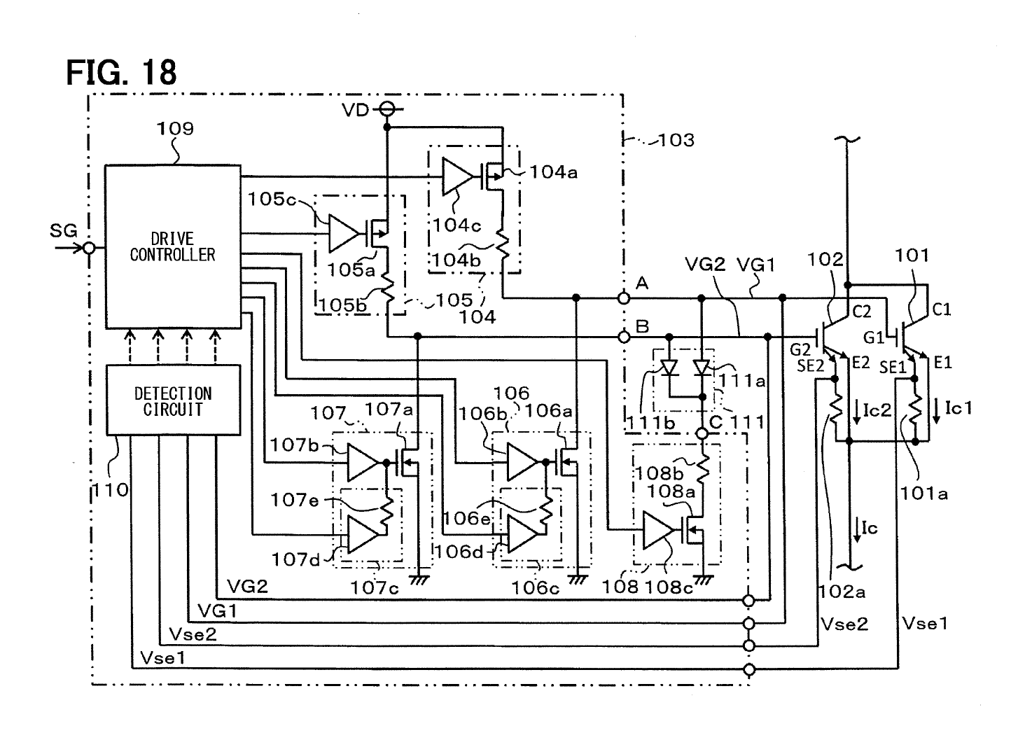

Next, a sixth embodiment will be described with reference to FIG. 18 to FIGS. 22A to 221.

In this embodiment, as shown in FIG. 18, two insulated gate bipolar transistors (IGBTs) 101, 102 are used as a plurality of gate-control semiconductor elements. The IGBT 101 has a sense emitter SE1 for monitoring a current in addition to a collector C1, an emitter E1, and a gate G1. Likewise, the IGBT 102 has a sense emitter SE2 for monitoring an element current in addition to a collector C2, an emitter E2, and a gate G2. The IGBTs 101, 102 are provided in a power supply path to a load (not shown), and have a configuration of a parallel drive system in which the collectors C1, C2 are connected in common and the emitters E1, E2 are connected in common.

On the basis of the externally applied gate switching signal SG, the two IGBTs 101, 102 are subjected to on/off drive control by a gate driving device 103. The gate driving device 103 includes a first gate cutoff circuit 104, a second gate cutoff circuit 105, a first gate-off circuit 106, a second gate-off circuit 107, a normal gate-off circuit 108, a drive control unit 109, and a detection circuit 110.

The first gate cutoff circuit 104 includes a p-channel MOSFET 104a, and the MOSFET 104a has a source connected to a DC power source VD and has a drain connected to a terminal A via a resistor 104b. A drive signal is applied from the drive control unit 109 to the gate of the MOSFET 104a via a driver 104c. The terminal A is connected to the gate of the IGBT 101 and outputs a gate drive voltage VG1.

The second gate cutoff circuit 105 includes a p-channel MOSFET 105a, and the MOSFET 105a has a source connected to the DC power source VD and has a drain connected to a terminal B via the resistor 105b. A drive signal is applied from the drive control unit 109 to the gate of the MOSFET 105a via a driver 105c. The terminal B is connected to the gate of the IGBT 102 and outputs the gate drive voltage VG2.

The first gate-off circuit 106 includes an n-channel MOSFET 106a as an off-MOSFET, and the MOSFET 106a has a drain connected to the terminal A and has a source connected to the ground. A drive signal is applied from the drive control unit 109 to the gate of the MOSFET 106a via the driver 106b. The first gate-off circuit 106 is configured to serve both as a gate-off fixing circuit and a high-speed gate-off circuit for the IGBT 101, and the MOSFET 106a is configured to be shared.

A first gate-off fixing path is formed by the MOSFET 106a and the driver 106b. In addition, a drive signal is applied from the drive control unit 109 to the gate of the MOSFET 106a via a first high-speed off unit 106c. The first high-speed off unit 106c applies a drive signal from a driver 106d to the gate of the MOSFET 106a via a gate resistor 106e. A first high-speed gate-off path is formed by the MOSFET 106a and the first high-speed off unit 106c.

The second gate-off circuit 107 includes an n-channel MOSFET 107a as an off-MOSFET, and the MOSFET 107a has a drain connected to the terminal B and has a source connected to the ground. The second gate-off circuit 107 is configured to serve both as a gate-off fixing circuit and a high-speed gate-off circuit for the IGBT 102, and the MOSFET 107a is configured to be shared.

A drive signal is applied from the drive control unit 109 to the gate of the MOSFET 107a via a driver 107b. The MOSFET 107a and the driver 107b constitute a second gate-off fixing circuit. In addition, a drive signal is applied from the drive control unit 109 to the gate of the MOSFET 107a via a second high-speed off unit 107c. The second high-speed off unit 107c applies a drive signal from a driver 107d to the gate of the MOSFET 107a via a gate resistor 107e. The second high-speed gate-off circuit is made up of the MOSFET 107a and the second high-speed off unit 107c.

A normal gate-off circuit 108, which forms a normal gate-off path, includes an n-channel MOSFET 108a, and the MOSFET 108a has a drain connected to a terminal C via a resistor 108b and has a source connected to the ground. A drive signal is applied from the drive control unit 109 to the gate of the MOSFET 108a via a driver 108c. The respective gates of the IGBTs 101, 102 are connected to the terminal C via a reverse current blocking unit 111. The reverse current blocking unit 111 includes two reverse current blocking diodes 111a, 111b, and prevent a reverse flow of a current between the gates of the IGBTs 101, 102.

The drive control unit 109 controls the drive of the IGBTs 101, 102 based on a gate switching signal SG applied from the outside and a detection signal from the detection circuit 110. The drive control unit 109 controls the drive of the IGBTs 101, 102 by applying the control signal to each of the first gate cutoff circuit 104, the second gate cutoff circuit 105, the first gate-off circuit 106, the second gate-off circuit 107, and the normal gate-off circuit 108 by an internally provided control circuit as described below.

The gate voltages VG1, VG2 of the IGBTs 101, 102 are input into the detection circuit 110. In addition, the detection circuit 110 receives input of voltages Vse1, Vse2 of the respective sense emitters of the IGBTs 101, 102. The detection circuit 110 converts these signals into digital signals and outputs the converted signals to the drive control unit 109. The sense voltages Vse1, Vse2 are voltage signals corresponding to element currents Ic1, Ic2 of the IGBTs 101, 102.

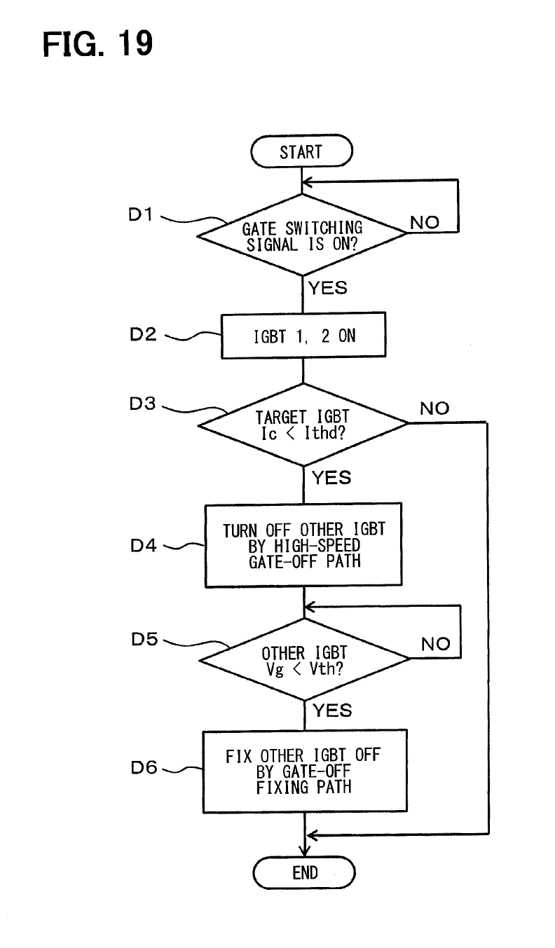

Next, the action of the above configuration will be described with reference also to FIG. 19 to FIGS. 21A to 21I.

In this embodiment, at the time of performing drive control on the IGBTs 101, 102, the drive control unit 109 turns on the two IGBTs 101, 102 simultaneously when the externally applied gate switching signal SG becomes a high level, namely, an turn-on operation instruction.

Thereafter, when both the element currents Ic1, Ic2 flowing through the IGBTs 101, 102 are between a lower limit value Ithd and an upper limit value Ithu, the drive control unit 109 drives the two IGBTs 101, 102 as they are.

When the levels of the element currents Ic1, Ic2 flowing through the IGBTs 101, 102 in the on-state are smaller than the lower limit value Ithd, the drive control unit 109 turns off one of the IGBTs to perform control so that the losses such as the switching loss and the on-resistance loss are minimized. At this time, for example, when the IGBT 102 is turned off, the element current Ic1 of the IGBT 101 is increased by addition of the element current Ic2 flowing through the IGBT 102, but this element current Ic1 has been set to fall within the range of the upper limit value Ithu.

In this way, in the case of performing the drive control on the IGBTs 101, 102, when the element current Ic1 (Ic2) of one of the IGBTs 101, 102 in operation is between the upper limit value Ithu and the lower limit value Ithd, the on-state remains held. When the element current Ic1 (Ic2) of the IGBT 101 or the IGBT 102 is smaller than the lower limit value Ithd in a state where both of the IGBTs 101, 102 are on, either of them is turned off. In a state where one of the two IGBTs 101, 102 is turned on, when the element current Ic1 (Ic2) exceeds the upper limit value Ithu, the one in the off-state is also turned on.

In the above case, when the IGBT 102 is always turned off in the operation of turning off one of the IGBTs, the life of the IGBT 101 is shortened. Therefore, when one of the IGBTs is to be turned off, the drive control unit 109 performs control so that, for example, the IGBTs 101, 102 are alternately turned off to average the lives thereof.

Next, the above operation will be described with reference to a flowchart of FIG. 19. First, a case where the IGBTs 101, 102 are driven to be turned on will be described. When a high-level gate switching signal SG indicating an turn-on operation instruction is input from the outside in step D1, the drive control unit 109 proceeds to step D2 to drive the IGBTs 101, 102 to be turned on. In this case, the drive control unit 109 outputs a low-level drive signal to each of a first gate cutoff circuit 103 and a second gate cutoff circuit 104 so as to turn on p-channel MOSFETs 103a, 104a.

Thereby, the gate voltages VG1, VG2 are applied to the gates of the IGBTs 101, 102, respectively, so that the IGBTs 101, 102 are turned on and the element currents Ic1, Ic2 flow therethrough, respectively. At this time, a sense current also flows through each of sense emitters SE of the IGBTs 101, 102, so that the sense voltages Vse1, Vse2 corresponding to the element currents Ic1, Ic2 are generated.

The drive control unit 109 proceeds to step D3 to determine whether or not the level of the element current Ic1 of the IGBT 101 as the object of the holding state is lower than the lower limit value Ithd, between the collector currents Ic1, Ic2 of the IGBTs 101, 102, which are input from the detection circuit 110. Here, when the element current Ic1 of the IGBT 101 is equal to or greater than the lower limit value Ithd, the drive control unit 109 determines NO and holds the on-state of the IGBTs 101, 102 as it is.

On the other hand, when the element current Ic1 of the IGBT 101 is lower than the lower limit value Ithd, the drive control unit 109 determines YES in step D3 and proceeds to step D4, where a second high-speed gate-off path is formed by the second gate-off circuit 107 to turn off the IGBT 102. In this case, the drive control unit 109 first turns off the second gate cutoff circuit 105 to cut off the gate voltage VG2 of the IGBT 102. Subsequently, the drive control unit 109 drives the second high-speed off unit 107c of the second gate-off circuit 107 to turn on the MOSFET 107a.

At this time, a drive signal is applied to the gate of the MOSFET 107a from the driver 107d via the resistor 107e. Thereby, the MOSFET 107a can be turned on at a high speed while avoiding breakdown due to a sudden change in the gate voltage, to quickly turn off the IGBT 102.

Thereafter, in step D5, the drive control unit 109 monitors the gate voltage Vg2 of the turned-off IGBT 102 and determines whether or not the gate voltage Vg2 is lower than a threshold voltage Vth. In the case of YES in step D5, the drive control unit 109 proceeds to step D6, drives the second gate-off circuit 107 to form a gate-off fixing path, and controls the IGBT 102 so as to be in the off-fixed state.

Here, the drive control unit 109 outputs an on-drive signal to the driver 107b of the second gate-off circuit 107 to hold the gate voltage of the MOSFET 107a surely to be in a high state, thereby fixing the off-state.

As described above, the drive control unit 109 simultaneously turns on the two IGBTs 101, 102, and then performs control as to whether the on-states of the two IGBTs are held according to the level of the element current Ic1, namely, the level of the load current, or the IGBT 102 is turned off and only the IGBT 101 is held in the on-state.

Even when the drive control unit 109 continues to hold both of the two IGBTs 101, 102 in the on-state among the above-described control, in a case where a load current decreases during the on-drive or other cases, the operations of steps D3 to C6 described above can be performed. Further, of the two IGBTs 101, 102, the IGBT 101 is held in the on-state in step D3, but in the next operation, a setting is made to hold the IGBT 102 in the on-state in step D3. This is for averaging the lives of the IGBTs 101, 102.

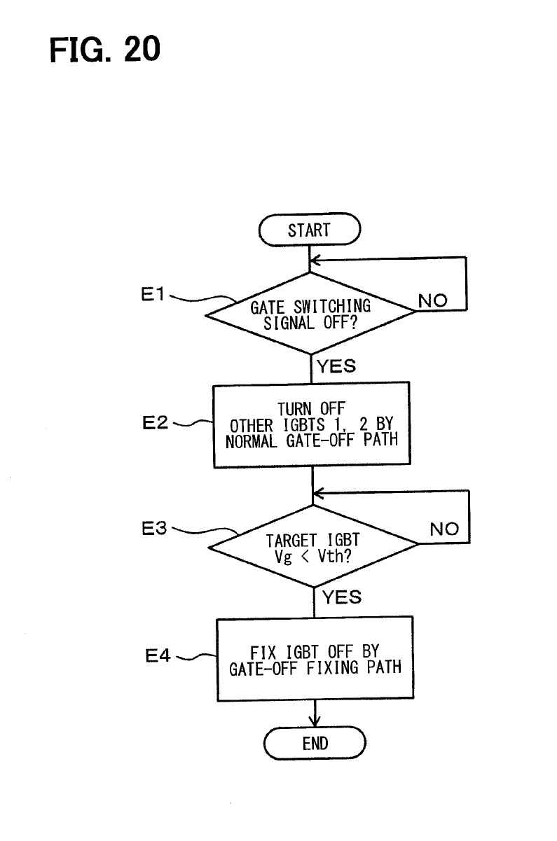

Next, the operation in a case where the gate switching signal SG from the outside changes to the off-state will be described with reference to FIG. 20.

As shown in FIG. 20, when the turn-off operation gate switching signal SG is applied from the outside, in the off-time processing, the drive control unit 109 determines YES in step E1 and proceeds to step E2. The drive control unit 109 outputs an off-drive signal to the driver 108c of the normal gate-off circuit 8 to turn on the MOSFET 108a. As a result, the gates are pulled to the ground via diodes 111a, 111b, the resistor 108b, and the MOSFET 108a, and the IGBTs 101, 102 are shifted to the off-state.

When the gate voltages Vg1, Vg2 decrease and fall below the threshold value Vth, the drive control unit 109 determines YES in step E3 and shifts to step E4, where the drive control unit 109 drives the first gate-off circuit 106 and the second gate-off circuit 107 to form an off fixing path and turn and fix the IGBTs 101, 102 off. In this case, regardless of whether both the IGBTs 101, 102 are in the on-state or only one of the IGBTs is in the on-state, the above control operation is performed.

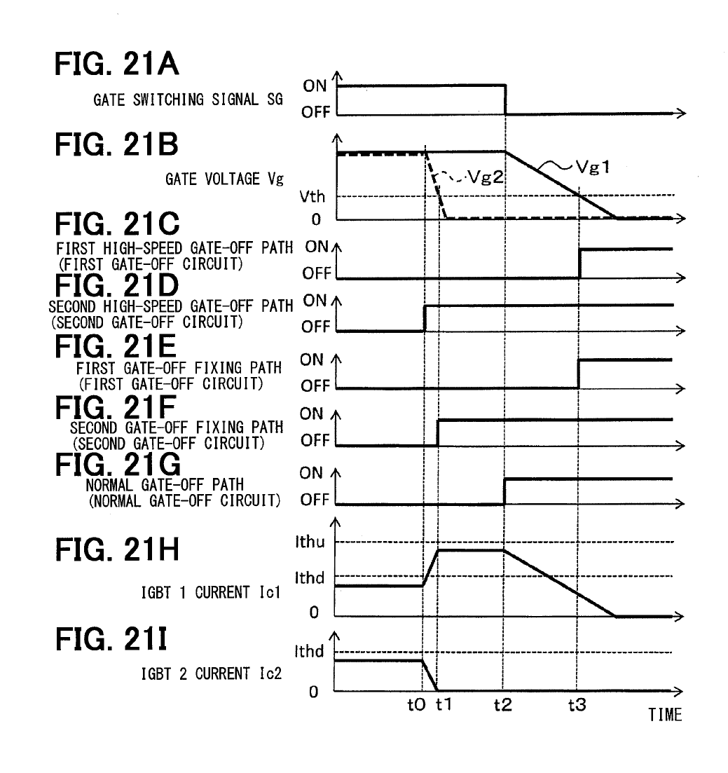

FIGS. 21A to 21I are a time chart of the operation in a case where the turn-off operation gate switching signal SG is input at a time t2 when only one of the IGBTs is in the on-state in the off-time processing described above. In this case, prior to the above operation, the drive control unit 109 has turned off the IGBT 102, for example, at a time to.

In the turn-off operation of the IGBT 102, the drive control unit 109 turns off the second gate cutoff circuit 105 to turn off the MOSFET 105a and cut off the gate voltage VG2. Subsequently, the drive control unit 109 drives the second high-speed off unit 107c of the second gate-off circuit 107 to turn on the MOSFET 107a via the gate resistor 107e. Thereby, as shown in FIG. 21D, a second high-speed gate-off path is formed by the second gate-off circuit 107.

In this state, since the IGBT 101 is in the turn-on operation, the generation of the surge current can be reduced in the turn-off operation of the IGBT 102, so that the turn-off operation can be performed at a high speed. Then, as shown in FIG. 21B, when the gate voltage Vg2 of the IGBT 102 decreases to the threshold voltage Vth at a time t1, the drive control unit 109 outputs a drive signal to the driver 107b to hold the MOSFET 107a into the on-state. As shown in FIG. 21F, the second gate-off circuit 107 forms a second gate-off fixing path to fix the IGBT 102 off.

Due to the operation as described above, the IGBT 102 is held in the off-state as shown in FIG. 21I, and the IGBT 101 is held in the on-state as shown in FIG. 21H. Thereafter, as shown in FIG. 21A, when the low-level gate switching signal SG as the turn-off operation instruction is applied at a time t2, the drive control unit 109 drives the normal gate-off circuit 8 to turn off the IGBT 101. At this time, as shown in FIG. 21G, the MOSFET 108a of the normal gate-off circuit 108 forms a normal gate-off path at the gate of the IGBT 101 via the resistor 108b and a reverse blocking diode 111a. Thereby, the gate voltage Vg1 of the IGBT 101 lowers slowly as shown in FIG. 21B, and the element current Ic1 also decreases slowly as the gate voltage Vg1 decreases as shown in FIG. 21H. Thereafter, when the gate voltage Vg1 of the IGBT 101 falls below the threshold voltage Vth at a time t3 as shown in FIG. 21B, the first gate-off circuit 106 turns on the MOSFET 106a to form a first gate-off fixing path as shown in FIG. 21E, and the IGBT 101 is fixed into the off-state. As shown in FIG. 21C, the first high-speed off unit 106c is also driven simultaneously at a time t3.

In the above operation, in the case of turning off the IGBT 101 while the two IGBTs 101, 102 are in the turn-on operation, the drive control unit 109 turns off the first gate cutoff circuit 104 and subsequently drives the first high-speed off unit 106c of the first gate-off circuit 106 to form a first high-speed gate-off path, so that the generation of surge current is reduced and the IGBT 101 can be turned off at a high speed. When the gate voltage Vg1 of the IGBT 101 reaches the threshold voltage Vth, the drive control unit 109 outputs a drive signal to the driver 106b to form a first gate-off fixing path by the first gate-off circuit 106 and fix the IGBT 101 off.

Thereafter, in the operation of turning off the IGBT 102 by application of the low-level gate switching signal SG as the turn-off operation instruction, the drive control unit 109 causes the normal gate-off circuit 108 to be operated in the same manner as described above, so that the gate voltage Vg2 decreases slowly and the element current Ic2 also decreases slowly, to turn off the IGBT102. Thereafter, when the gate voltage Vg2 of the IGBT 102 falls below the threshold voltage Vth, the second gate-off circuit 107 forms a second gate-off fixing path, to fix the IGBT 102 into the off-state.

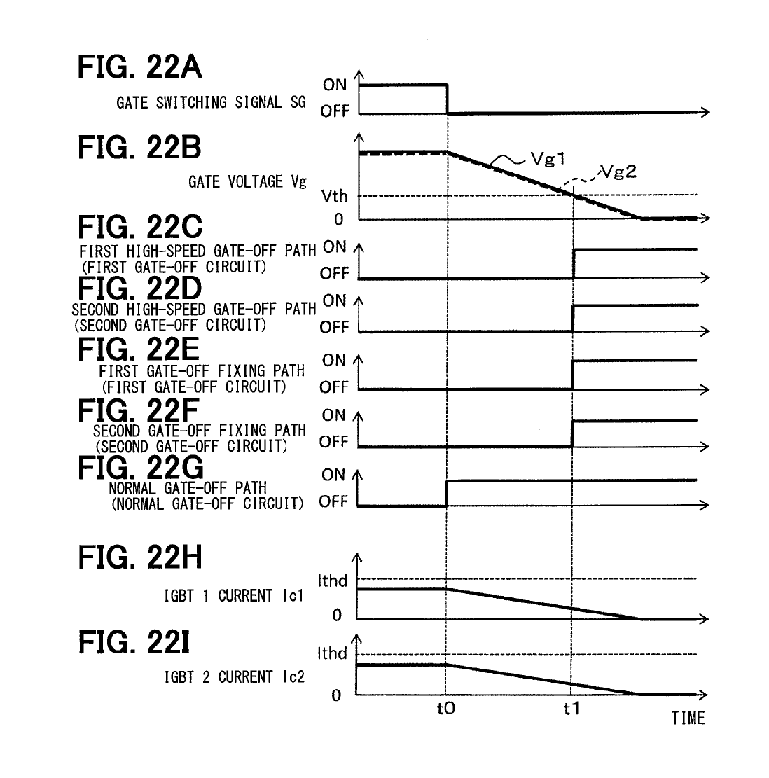

FIGS. 22A to 221 are a time chart of the operation in the case of application of the turn-off operation gate switching signal SG from a state where the two IGBTs 101, 102 are both turned on when the above-described off-time processing is performed.

In this case, when the turn-off operation gate switching signal SG is input at a time t0 as shown in FIG. 22A, the drive control unit 109 drives the normal gate-off circuit 108 to form the normal gate-off path as shown in FIG. 22G. As a result, both the IGBTs 101, 102 are shifted to the off-state. At this time, the gate voltages Vg1, Vg2 decrease slowly in the IGBTs 101, 102 as shown in FIG. 22A, and the element currents Ic1, Ic2 also decrease slowly as shown in FIGS. 22H and 221. Thereafter, as shown in FIG. 22B, when the gate voltages Vg1, Vg2 of the IGBTs 101, 102 fall below the threshold voltage Vth at a time t1, as shown in FIGS. 22E and 22F, the first gate-off circuit 106 and the second gate-off circuit 107 form gate-off fixing paths, to fix the IGBTs 101, 102 into the off-state. As shown in FIGS. 22C and 22D, the first and second high-speed off units 106c, 107c are simultaneously driven at a time t1.

According to the present embodiment, in the configuration where the two IGBTs 101, 102 are connected in parallel for drive control, the normal gate-off circuit 108 is provided while the first and second gate-off circuits 106, 107 are provided, and the drive control unit 109 performs the turn-off operation control.

Thereby, in the operation where both of the two IGBTs 101, 102 are in the on-state and one of the IGBTs is turned off, a high-speed gate-off path is formed using one of the first and second gate-off circuits 106, 107 to quickly turn off the one IGBT, and an off fixing path is then formed to hold the off-state, so that it is possible to quickly perform the turn-off operation.

When the gate switching signal SG is an turn-off operation instruction, one of the two IGBTs 101, 102 which is in the turn-on operation is turned off by the normal gate-off circuit 108 forming a normal gate-off path. It is thereby possible to reliably perform the turn-off operation while preventing element destruction due to generation of a surge current.

Further, the first gate-off circuit 106 (second gate-off circuit 107) is configured such that the n-channel MOSFET 106a (107a) as the off-MOSFET is driven in common between the high-speed off unit 106c (107c) and the driver 106b (107b), so that the number of elements can be small as compared to a configuration where off-MOSFETs are provided individually, to enable space saving.

### Other Embodiments

The present disclosure is not limited only to the above-described embodiments, but can be applied to various embodiments without departing from the gist thereof, and can be modified or expanded as follows, for example.

Four or more IGBTs can be provided as a plurality of semiconductor elements.

As the gate-driven semiconductor element, besides the IGBT, it is possible to provide a MOSFET and the like of the gate-driven type.

The current detection circuits 10, 11, and 33 to 35 have been configured to determine the current level by using the comparator that compares currents with reference to the threshold current. However, the current value may be read by an analog-digital (A/D) conversion circuit or the like and the current level may be determined in the control circuit 9 or 32.

The on/off control of the IGBT has been performed by the hardware processing using the logic circuit by the control circuits 9 and 32, but can also be performed by software using a program.

In the above sixth embodiment, the example where two IGBTs 101, 102 are provided as semiconductor elements has been shown, but the present invention can also be applied to a configuration in which three or more IGBTs are provided.

Further, in the case where three or more IGBTs are provided, after all of the IGBTs are turned on simultaneously during the turn-on operation, when the value of the element current is equal to or smaller than the lower limit value, instead of setting all of the remaining IGBTs as the targets to be turned off with respect to the IGBTs held in the on-state, some of the remaining IGBTs can be set as the objects to be turned off. That is, in step D4 shown in FIG. 19, it is possible to set “some of the IGBTs off in the high-speed off circuit.”

In the sixth embodiment, the example in which the two IGBTs 101, 102 are turned on simultaneously by the gate switching signal of the turn-on operation has been described, but it is also possible to adopt a method of turning on the IGBTs one by one in turn. In this case, for example, the IGBT 102 is controlled so as to be turned on when the current at the time of turning on the IGBT 101 exceeds the upper limit value.

Further, the example has been shown where one IGBT 101 is held in the on-state and the other IGBT 102 is turned off when the value of the element current is equal to or smaller than the lower limit value, the IGBT to be turned off can be changed and set. In this case, the IGBT to be turned off may be alternately set and changed each time one IGBT becomes the object to be turned off, or may be changed and set so that the use time is averaged when, for example, the use time is counted in advance and a certain difference or more occurs.

In the sixth embodiment, in the first gate-off circuit 106 and the second gate-off circuit 107, the gate-off fixing path is formed by the configuration of directly applying the signals from the drivers 106b, 107b to the MOSFETs 106a, 107a. However, the gate-off fixing path can also be formed by a configuration where a gate resistor with lower resistance than those of the gate resistors 106e, 107e, or an impedance element with low impedance is interposed.

Although the example of using the IGBT as the gate-driven semiconductor element has been described, the present invention is not limited to this, but can be applied to a semiconductor element such as a MOSFET.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

1. A gate driving device for driving a plurality of semiconductor elements, which are gate driven, connected in parallel, the plurality of semiconductor elements including a start-up semiconductor element and at least one next-stage driving semiconductor element having a final-stage driving semiconductor element, the gate driving device comprising:
a current detection circuit that detects a current of each of the semiconductor elements other than the final-stage driving semiconductor element;
a constant current circuit that performs gate drive on the start-up semiconductor element at a constant current;
a selector switch that disables the constant current circuit and performs the gate drive on the next-stage driving semiconductor element and the final-stage driving semiconductor element at a constant voltage; and
a control circuit that drives and controls the plurality of semiconductor elements,
wherein:
the control circuit receives a driving signal for a turn-on operation from outside to execute a start-up control and a next-stage drive control, and to repetitively execute the next-stage drive control in response to the next-stage driving semiconductor element in an off-state being subsequently present;
in the start-up control, the control circuit applies a gate signal to the start-up semiconductor element at the constant current by the constant current circuit to turn on the start-up semiconductor element;
in the next-stage drive control, the control circuit sets the selector switch into an operating state and applies the gate signal to the next-stage driving semiconductor element in an off-state at a constant voltage to turn on the next-stage driving semiconductor element, in response to a current detected by the current detection circuit provided in the semiconductor element being turned on reaching a threshold current; and
the threshold current is set such that a sum of an on-resistance loss and a switching loss caused by all the semiconductor elements in an on-state is smaller than the sum of the on-resistance loss and the switching loss before execution of the next-stage drive control, in response to the next-stage driving semiconductor element among the plurality of semiconductor elements being turned on to allow a current to flow.

2. The gate driving device according to claim 1, wherein
the plurality of semiconductor elements includes a plurality of the next-stage driving semiconductor elements; and
the control circuit is configured to enable changing a sequential order of turning on the start-up semiconductor element and the next-stage driving semiconductor elements other than the final-stage driving semiconductor element.

3. The gate driving device according to claim 1, wherein:
the current detection circuit is provided in each of the plurality of semiconductor elements; and
the control circuit is configured to enable changing a sequential order of turning on the plurality of semiconductor elements.

4. The gate driving device according to claim 1, wherein
in a state where more than one of the plurality of semiconductor elements are turned on, the control circuit turns off the semiconductor elements, which are turned on, at different timings.

5. The gate driving device according to claim 1, wherein
in a state where more than one of the plurality of semiconductor elements are turned on, the control circuit turns off any semiconductor element among the plurality of semiconductor elements being turned on in response to a current value detected by the current detection circuit falling below a preset threshold current value.

6. The gate driving device according to claim 1, wherein
in a state where any of the plurality of semiconductor elements is turned on, the control circuit performs the next-stage drive control on the semiconductor element in the off-state among the plurality of semiconductor elements.

7. A gate driving device for turning on and off a plurality of semiconductor elements, which are gate driven, connected in parallel and setting a semiconductor element to be held in an on-state among the plurality of semiconductor elements based on a current flowing in the plurality of semiconductor elements under a condition with a switching loss and an on-resistance loss associated with a turn-on operation resulting in decrease,
the gate driving device comprising:
a normal gate-off circuit that turns off all the plurality of semiconductor elements; and
a high-speed gate-off circuit that turns off a part of the plurality of semiconductor elements in response to the part of the semiconductor elements in the on-state,
wherein:
the normal gate-off circuit is configured to change a gate voltage at a slower speed to turn off the plurality of semiconductor elements so that a surge current generated in turning off the plurality of semiconductor elements is equal to or smaller than a breakdown tolerance; and
the high-speed gate-off circuit is configured to change the gate voltage at a faster speed than the normal gate-off circuit to turn off the part of the plurality of semiconductor elements.

8. The gate driving device according to claim 7,
wherein the high-speed gate-off circuit is provided in the part of the plurality of semiconductor elements to be turned off, and
the gate driving device further comprises
a controller that changes and sets the semiconductor element to be turned off in response to the high-speed gate-off circuit turning off the part of the plurality of semiconductor elements.

9. The gate driving device according to claim 7, comprising:
a detector that detects whether a gate voltage of the semiconductor element to be turned off falls below a threshold voltage by the high-speed gate-off circuit; and
a gate-off fixing circuit that fixes a gate voltage of the semiconductor element to be turned off to an off-level in response to the detector detecting the gate voltage of the semiconductor element to be turned off falling below the threshold voltage.

10. The gate driving device according to claim 7, wherein
the high-speed gate-off circuit includes
an off-MOSFET that allows a current to flow, the current being used at a change in the gate voltage of the semiconductor element to an off-level, and
a gate resistor that is connected to a gate of the off-MOSFET to allow the current to flow within a current rating range of the off-MOSFET.

11. The gate driving device according to claim 9, wherein:
the high-speed gate-off circuit includes
an off-MOSFET that allows a current to flow, the current being used at a change in the gate voltage of the semiconductor element to an off-level, and
a gate resistor that is connected to a gate of the off-MOSFET to allow the current to flow within a current rating range of the off-MOSFET; and
the gate-off fixing circuit is configured to share the off-MOSFETs with the high-speed gate-off circuit, and is provided as a path to drive the gate of the off-MOSFET via a low-resistance gate resistor having a resistance value smaller than a resistance value of the gate resistor or without passing through a resistor.
